(19) United States
(12) Patent Application Publication
(10) Pub. No.: US 2026/0164801 A1
(43) Pub. Date: Jun. 11, 2026

(54) ARRAY SUBSTRATE, METHOD FOR MANUFACTURING ARRAY SUBSTRATE, AND DISPLAY PANEL

(71) Applicants: Beijing BOE Technology Development Co., Ltd., Beijing (CN); BOE Technology Group Co., Ltd., Beijing (CN)

(72) Inventors: Binbin TONG, Beijing (CN); Ce NING, Beijing (CN); Lizhong WANG, Beijing (CN); Tianmin ZHOU, Beijing (CN); Jinchao ZHANG, Beijing (CN); Rui HUANG, Beijing (CN); Hui GUO, Beijing (CN)

(73) Assignees: Beijing BOE Technology Development Co., Ltd., Beijing (CN); BOE Technology Group Co., Ltd., Beijing (CN)

(21) Appl. No.: 18/992,214

(22) PCT Filed: Apr. 24, 2024
(86) PCT No.: PCT/CN2024/089529

§ 371 Date: Jan. 8, 2025

(30) Foreign Application Priority Data
May 31, 2023 (CN) 202310635699.8

(51) Int. Cl. H10D 86/40; G02F 1/1362; H10D 86/01

(52) U.S. Cl. CPC H10D 86/441; G02F 1/136286; H10D 86/0231

(57) ABSTRACT

Provided is an array substrate. The array substrate includes: a substrate, multiple data lines disposed on a side of the substrate, multiple active patterns disposed on a side, distal to the substrate, of the multiple data lines, wherein the multiple active patterns correspond to the multiple data lines, and each active pattern includes a first conductive section and two second conductive sections disposed on two sides of the first conductive section, respectively, and the first conductive section of the active pattern is electrically connected to a data line corresponding to the first conductive section; and multiple pixel electrodes disposed on a side, distal to the substrate, of the multiple active patterns, wherein the two second conductive sections in the active pattern are electrically connected to two different pixel electrodes, respectively.

### CROSS-REFERENCE TO RELATED APPLICATIONS

This application is a U.S. national stage of international application No. PCT/CN2024/089529, filed on Apr. 24, 2024, which claims priority to Chinese Patent Application No. 202310635699.8, filed on May 31, 2023, and entitled “ARRAY SUBSTRATE AND MANUFACTURING METHOD THEREFOR, AND DISPLAY PANEL”, the contents of each are incorporated herein by reference in their entirety.

### TECHNICAL FIELD

The present disclosure relates to the field of display technologies, in particular to an array substrate, a method for manufacturing the array substrate, and a display panel.

### BACKGROUND

A liquid crystal display panel has the characteristics of small size, low power consumption, no radiation, and the like, which occupies a dominant position in the current display market.

In general, the liquid crystal display panel includes an array substrate, a color filter substrate, and a liquid crystal layer. The array substrate is arranged oppositely to the color filter substrate, and the liquid crystal layer is arranged between the array substrate and the color filter substrate. The array substrate integrates multiple thin-film transistors (TFT) and pixel electrodes electrically connected to the multiple TFTs in one-to-one correspondence in the display region.

### SUMMARY

Embodiments of the present disclosure provide an array substrate, a method for manufacturing an array substrate, and a display panel. The described technical solutions are given as follows.

According to some embodiments of the present disclosure, an array substrate is provided. The array substrate includes:
substrate;
multiple data lines disposed on a side of the substrate;
multiple active patterns disposed on a side, distal to the substrate, of the multiple data lines, wherein the multiple active patterns correspond to the multiple data lines, and each active pattern includes a first conductive section and two second conductive sections disposed on two sides of the first conductive section, respectively, and the first conductive section of the active pattern is electrically connected to a data line corresponding to the first conductive section; and
multiple pixel electrodes disposed on a side, distal to the substrate, of the multiple active patterns, wherein the two second conductive sections in the active pattern are electrically connected to two different pixel electrodes, respectively.

In some embodiments, the array substrate further includes multiple gate lines disposed on the side, distal to the substrate, of the multiple active patterns, the gate lines being insulated from the active patterns; wherein
each active pattern further includes two channel areas disposed between the first conductive section and the two second conductive sections, respectively, wherein the two channel areas in the active pattern correspond to two different the gate lines, and an orthographic projection of each channel area on the substrate overlaps an orthographic projection of the gate line corresponding to the channel area on the substrate.

In some embodiments, two gate lines corresponding to the two channel areas in the active pattern are arranged adjacent to each other.

In some embodiments, the multiple data lines are arranged sequentially in a first direction, the multiple gate lines are arranged sequentially in a second direction, the two second conductive sections in each active pattern are respectively arranged on two sides of the data line corresponding to the active pattern in the first direction and respectively arranged on two outer sides of the two gate lines corresponding to the two channel areas in the active pattern in the second direction.

In some embodiments, the first conductive section in each active pattern includes a first portion disposed on one side of the data line corresponding to the active pattern, and a second portion disposed on another side of the data line corresponding to the active pattern;
for two adjacent columns of the active patterns, multiple first portions in one column of the active patterns and multiple second portions in another column of the active patterns are disposed between two adjacent data lines and are alternately arranged.

In some embodiments, the two channel areas in each active pattern include a first channel area adjacent to the first portion and a second channel area adjacent to the second portion;
for two adjacent rows of the active patterns, multiple first channel areas in one row of the active patterns are alternately arranged with multiple first channel areas in another row of the active patterns, and the multiple first channel areas in one row of the active pattern and the multiple first channel areas in another row of the active patterns are all overlapped with a same first gate line;
wherein the first gate line is one of the multiple gate lines.

In some embodiments, in two adjacent rows of the active patterns, multiple second channel areas in one row of the active patterns are all overlapped with a same second gate line, and multiple second channel areas in another row of the active patterns are all overlapped with a same third gate line; and
wherein the second gate line is one of the multiple gate lines disposed on one side of the first gate line, and the third gate line is one of the multiple gate lines disposed on another side of the first gate line.

In some embodiments, the array substrate further includes multiple auxiliary electrodes disposed on the side, distal to the substrate, of the multiple active patterns, wherein the multiple auxiliary electrodes are in one-to-one correspondence with the multiple active patterns, and the first conductive section of each active pattern is connected to the data line corresponding to the active pattern via the auxiliary electrode corresponding to the active pattern.

In some embodiments, the multiple auxiliary electrodes and the multiple gate lines are provided in a same layer and made of a same material.

In some embodiments, the array substrate further includes a first interlayer dielectric layer and a gate insulation layer, wherein
the first interlayer dielectric layer is disposed on a side, distal to the substrate, of the multiple data lines, the multiple active patterns are disposed on a side, distal to the substrate, of the first interlayer dielectric layer; the gate insulation layer is disposed on the side, distal to the substrate, of the multiple active patterns, and the multiple gate lines and the multiple auxiliary electrodes are disposed on a side, distal to the substrate, of the gate insulation layer;
wherein the array substrate is provided with a first via hole penetrating through the interlayer dielectric layer and a second via hole penetrating through the gate insulation layer and the first interlayer dielectric layer, the first conductive section is connected to the data line through the first via hole, and the auxiliary electrode is respectively connected to the data line and the first conductive section through the second via hole.

In some embodiments, a part of an orthographic projection of the second via hole on the substrate is disposed within an orthographic projection of the first via hole on the substrate, and another part is disposed outside the orthographic projection of the first via hole on the substrate.

In some embodiments, the array substrate further includes: multiple transfer electrodes one-to-one corresponding to the multiple pixel electrodes, wherein the multiple transfer electrodes are disposed between the multiple active patterns and the multiple pixel electrodes in a direction perpendicular to the substrate, and each pixel electrode is electrically connected to the second conductive section corresponding to the pixel electrode via the transfer electrode corresponding to the pixel electrode.

In some embodiments, the array substrate further includes: a gate insulation layer, a second interlayer dielectric layer, and a planarization layer; wherein the gate insulation layer is disposed on the side, distal to the substrate, of the multiple active patterns, the multiple gate lines are disposed on the side, distal to the substrate, of the gate insulation layer; the second interlayer dielectric layer is disposed on a side, distal to the substrate, of the multiple gate lines, the multiple transfer electrodes are disposed on a side, distal to the substrate, of the second interlayer dielectric layer; the planarization layer is disposed on a side, distal to the substrate, of the multiple transfer electrodes, and the multiple pixel electrodes disposed on a side, distal to the substrate, of the planarization layer;
wherein the array substrate is provided with a third via hole penetrating through the planarization layer and a fourth via hole penetrating through the second interlayer dielectric layer and the gate insulation layer, each pixel electrode is connected to the transfer electrode corresponding to the pixel electrode through the third via hole, and the transfer electrode is connected to the second conductive section corresponding to the pixel electrode through the fourth via hole.

In some embodiments, each transfer electrode includes a first adapter sub-electrode and a second adapter sub-electrode, an orthographic projection of the first adapter sub-electrode on the substrate being located within an orthographic projection of the gate line on the substrate, and an orthographic projection of the second adapter sub-electrode on the substrate being located outside the orthographic projection of the gate line on the substrate; and
wherein an orthographic projection of the third via hole on the substrate overlaps the orthographic projection of the first adapter sub-electrode on the substrate, and an orthographic projection of the fourth via hole on the substrate overlaps the orthographic projection of the second adapter sub-electrode on the substrate.

In some embodiments, the multiple transfer electrodes are transparent electrodes.

In some embodiments, the array substrate further includes a passivation layer disposed on a side, distal to the substrate, of the multiple pixel electrodes, and a support layer disposed on a side, distal to the substrate, of the passivation layer, wherein a part of the support layer is filled in the third via hole, and another part of the support layer projects with respect to the side, distal to the substrate, of the passivation layer.

In some embodiments, the support layer includes multiple support strips in one-to-one correspondence with the multiple gate lines, and an orthographic projection of each support strip on the substrate covers the orthographic projection of the gate line corresponding to the support strip on the substrate.

In some embodiments, the multiple support strips include multiple support strip bodies, and support pillars disposed between two adjacent the support strip bodies, a width of the support pillar being greater than a width of the support strip body in an arrangement direction of the multiple gate lines.

In some embodiments, the array substrate further includes multiple auxiliary shading strips disposed on a side, proximate to the substrate, of the multiple active patterns, wherein the multiple auxiliary shading strips are in one-to-one correspondence with the multiple gate lines, an orthographic projection of each auxiliary shading strip on the substrate covers the orthographic projection of the gate line corresponding to the auxiliary shading strip on the substrate, and the orthographic projection of the channel area in the active pattern is located within the orthographic projection of the auxiliary shading strip on the substrate.

In some embodiments, the array substrate further includes multiple common electrode strips disposed on a side, distal to the substrate, of the multiple pixel electrodes, wherein the common electrode strips have light-shielding property, the multiple common electrode strips are in one-to-one correspondence with the multiple data lines, and an orthographic projection of each common electrode strip on the substrate cover an orthographic projection of the data line corresponding to the common electrode strip on the substrate.

According to some embodiments of the present disclosure, a method for manufacturing an array substrate is provided. The method includes:
forming multiple data lines on a side of the substrate;
forming multiple active patterns on a side, distal to the substrate, of the multiple data lines, wherein the multiple active patterns correspond to the multiple data lines, and each active pattern includes a first conductive section and two second conductive sections disposed on two sides of the first conductive section, respectively, and the first conductive section of the active pattern is electrically connected to a data line corresponding to the first conductive section;
forming multiple pixel electrodes on a side, distal to the substrate, of the multiple active patterns, wherein the two second conductive sections in the active pattern are electrically connected to two different pixel electrodes.

According to some embodiments of the present disclosure, a display panel is provided. The display panel includes: the array substrate as defined in any one of the above embodiments, a color filter substrate oppositely arranged to the array substrate, and a liquid crystal layer disposed between the array substrate and the color filter substrate.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description illustrate merely some embodiments of the present disclosure, and a person of ordinary skill in the art may still derive other drawings from these accompanying drawings without creative efforts.

FIG. 1 is a top view of an array substrate provided by the related art;

FIG. 2 is a schematic structural diagram of film layers of the array substrate illustrated in FIG. 1 along a tangent line A-A′;

FIG. 3 is a top view of an array substrate according to some embodiments of the present disclosure;

FIG. 4 is a schematic structural diagram of film layers of the array substrate illustrated in FIG. 3 along a tangent line B-B′;

FIG. 5 is a simplified schematic diagram of the array substrate shown in FIG. 3;

FIG. 6 is a top view of another array substrate according to some embodiments of the present disclosure;

FIG. 7 is a partially enlarged view of a single active pattern in the array substrate illustrated in FIG. 6;

FIG. 8 is a schematic structural diagram of film layers of the array substrate illustrated in FIG. 6 along a tangent line C-C′;

FIG. 9 is a top view of yet another array substrate according to some embodiments of the present disclosure;

FIG. 10 is a schematic structural diagram of film layers of the array substrate illustrated in FIG. 9 along a tangent line D-D′;

FIG. 11 is a partially enlarged view of a first via hole and a second via hole according to some embodiments of the present disclosure;

FIG. 12 is a top view of a still yet another array substrate according to some embodiments of the present disclosure;

FIG. 13 is a schematic structural diagram of film layers of the array substrate illustrated in FIG. 12 along a tangent line E-E′;

FIG. 14 is a top view of an array substrate according to some embodiments of the present disclosure;

FIG. 15 is a top view of another array substrate according to some embodiments of the present disclosure;

FIG. 16 is a schematic structural diagram of film layers of the array substrate illustrated in FIG. 15 along a tangent line F-F′;

FIG. 17 is a top view of an array substrate according to some embodiments of the present disclosure;

FIG. 18 is a schematic structural diagram of film layers of the array substrate illustrated in FIG. 17 along a tangent line G-G′;

FIG. 19 is a flowchart of a method for manufacturing an array substrate according to some embodiments of the present disclosure;

FIG. 20 is a schematic diagram showing multiple data lines have been formed on a substrate according to some embodiments of the present disclosure;

FIG. 21 is a schematic structural diagram of film layers corresponding to FIG. 20;

FIG. 22 is a schematic diagram showing that a first interlayer dielectric layer has been formed according to some embodiments of the present disclosure;

FIG. 23 is a schematic structural diagram of film layers corresponding to FIG. 22;

FIG. 24 is a schematic diagram showing that multiple active patterns have been formed according to some embodiments of the present disclosure;

FIG. 25 is a schematic structural diagram of film layers corresponding to FIG. 24;

FIG. 26 is a schematic diagram showing that a gate insulation layer and multiple gate lines have been formed according to some embodiments of the present disclosure;

FIG. 27 is a schematic structural diagram of film layers corresponding to FIG. 26;

FIG. 28 is a schematic diagram showing that a second interlayer dielectric layer has been formed according to some embodiments of the present disclosure;

FIG. 29 is a schematic structural diagram of film layers corresponding to FIG. 28;

FIG. 30 is a schematic diagram showing that multiple transfer electrodes have been formed according to some embodiments of the present disclosure;

FIG. 31 is a schematic structural diagram of film layers corresponding to FIG. 30;

FIG. 32 is a schematic diagram showing that multiple third via holes have been formed according to some embodiments of the present disclosure;

FIG. 33 is a schematic structural diagram of film layers corresponding to FIG. 32;

FIG. 34 is a schematic diagram showing that multiple pixel electrodes have been formed according to some embodiments of the present disclosure;

FIG. 35 is a schematic structural diagram of film layers corresponding to FIG. 34;

FIG. 36 is a schematic diagram showing that a passivation layer and multiple common electrode strips have been formed according to some embodiments of the present disclosure;

FIG. 37 is a schematic structural diagram of film layers corresponding to FIG. 36;

FIG. 38 is a schematic diagram showing that a support layer has been formed according to some embodiments of the present disclosure; and

FIG. 39 is a schematic structural diagram of film layers corresponding to FIG. 38.

### DETAILED DESCRIPTION

To make the objective, technical solutions, and advantages of the present disclosure clearer, embodiments of the present disclosure will be further described in detail with reference to the accompanying drawings.

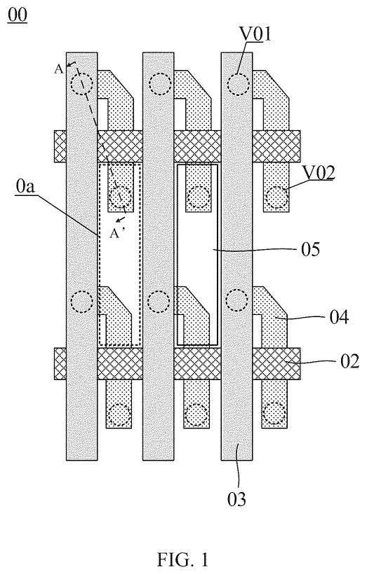

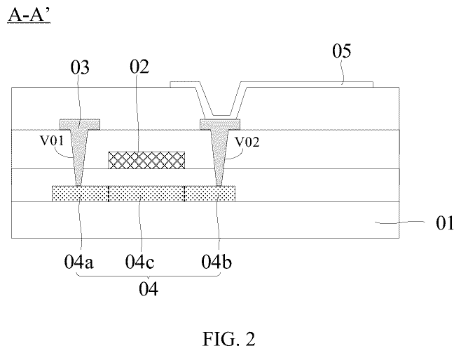

Referring to FIGS. 1 and 2, FIG. 1 is a top view of an array substrate provided by the related art, and FIG. 2 is a schematic structural diagram of film layers of the array substrate illustrated in FIG. 1 along a tangent line A-A′. The array substrate 00 includes a substrate 01 and multiple gate lines 02, multiple data lines 03, and multiple active patterns 04 that are disposed on a side of the substrate 01. The extension direction of the gate lines 02 is perpendicular to the extension direction of the data lines 03. In this way, two adjacent gate lines 02 and two adjacent data lines 03 enclose a sub-pixel region 0a, and a pixel electrode 05 is disposed in the sub-pixel region 0a.

The active pattern 04 is provided with a first conductive section 04a and a second conductive section 04b disposed opposite to each other, and a channel area 04c disposed between the first conductive section 04a and the second conductive section 04b. The first conductive section 04a is electrically connected to the data line 03 through a first via hole V01, the second conductive section 04b is electrically connected to the pixel electrode 05 through a second via hole V02, and an orthographic projection of the channel area 04c on the substrate 01 is located within an orthographic projection of the gate line 02 on the substrate 01. In this way, the active pattern 04, a part of the data line 03 connected to the first conductive section 04a of the active pattern 04, a part of the pixel electrode 05 connected to the second conductive section 04b of the active pattern 04, and a part of the gate line 02 overlapping with the channel area 04c of the active pattern 04 together form a TFT.

However, both the first via hole VOI and the second via hole V02 in the array substrate 00 are provided on one side of the active pattern 04 distal to the substrate 01. In the case that the size of the sub-pixel region 0a is too small, the horizontal distance between the first via hole V01 and the second via hole V02 is relatively close, which causes a high tendency for connecting the first via hole V01 to the second via hole V02, thereby resulting in a short-circuit between the data line 03 and the pixel electrode 05. For this reason, the size of the sub-pixel region 0a cannot be provided to be excessively small, which results in a low PPI of the array substrate 00.

In addition, each TFT in the array substrate 00 is connected to the data line 03 through the first via hole V01, thus the number of the first via holes V01 in the array substrate 00 for connecting the TFTs to the data lines 03 is too large. The excessive number of the first via holes V01 limits the size of the sub-pixel region Oa, which in turn leads to the larger size of the sub-pixel region 0a.

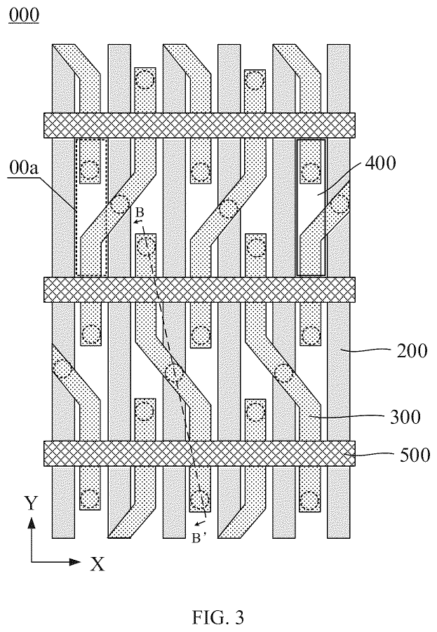

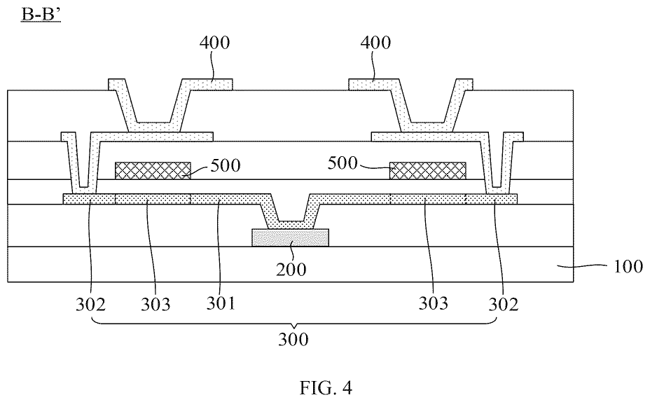

Referring to FIGS. 3 and 4, FIG. 3 is a top view of an array substrate according to some embodiments of the present disclosure, and FIG. 4 is a schematic structural diagram of film layers of the array substrate illustrated in FIG. 3 along a tangent line B-B′. The array substrate 000 includes: a substrate 100, multiple data lines 200, multiple active patterns 300, and multiple pixel electrodes 400.

The multiple data lines 200 in the array substrate 000 are disposed on a side of the substrate 100. The multiple data lines 200 may be disposed in sequence along the first direction X and be distributed in parallel.

The multiple active patterns 300 in the array substrate 000 are disposed on a side of the multiple data lines 200 distal to the substrate 100. The multiple active patterns 300 correspond to the multiple data lines 200, and each active pattern 300 includes: a first conductive section 301, and two second conductive sections 302 disposed on both sides of the first conductive section 301. The first conductive section 301 in each of the active patterns 300 is electrically connected to a corresponding data line 200.

Exemplarily, the multiple active patterns 300 are arrayed in multiple rows and multiple columns, the number of columns of the multiple active patterns 300 may be the same as the number of the multiple data lines 200, the multiple columns of active patterns 300 are in one-to-one correspondence with the multiple data lines 200, and each of the data lines 200 is electrically connected to the first conductive sections 301 of the active patterns 300 in the column of active patterns 300 corresponding to the data line 200.

The multiple pixel electrodes 400 in the array substrate 000 are disposed on a side of the multiple active patterns 300 distal to the substrate 100. Two second conductive sections 302 in each active pattern 300 are electrically connected to two different pixel electrodes 400, respectively.

In the present disclosure, the array substrate 000 may further include multiple gate lines 500 disposed on the side of the multiple active patterns 300 distal to the substrate 100. The gate lines 500 are insulated from the active patterns 300, and the multiple gate lines 500 in the array substrate 000 are disposed in sequence along the second direction Y and distributed in parallel. The second direction Y may intersect with the first direction X. For example, the second direction Y is perpendicular to the first direction X. In this way, the data line 200 extends along the second direction Y, and the gate lines 500 extends along the first direction X. That is, the extension direction of the data line 200 is perpendicular to the extension direction of the gate line 500. It should be noted that in the array substrate 000, any two adjacent data lines 200 and any two adjacent gate lines 500 enclose a sub-pixel region 00a, and a pixel electrode 400 is disposed in each sub-pixel region 00a.

The data line 200 is disposed on a side of the active pattern 300 proximate to the substrate 100, and the pixel electrode 400 is located on a side of the active pattern 300 distal to the substrate 100. Therefore, the first conductive section 301 in the active pattern 300 is electrically connected to the data line 200 through a via hole on the side proximate to the substrate 100, and the second conductive section 302 in the active pattern 300 is connected to the pixel electrode 400 through a via hole on the side distal to the substrate 100. That is, the via hole for connecting the first conductive section 301 to the data line 200 and the via hole for connecting the pixel electrode 400 to the second conductive section 302 are provided on the two opposite sides of the active pattern 300 in the array substrate 000. In this way, even if the horizontal distance between the via hole for connecting the first conductive section 301 to the data line 200 and the via hole for connecting the pixel electrode 400 to the second conductive section 302 is small due to the small size of the sub-pixel region 00a, it can be ensured that the two via holes are not connected, thereby avoiding the short-circuit between the data line 200 and the pixel electrode 400. Further, it can be ensured that the size of the sub-pixel region 00a in the array substrate 000 is no longer affected by the horizontal distance between the two via holes, which makes the size of the sub-pixel region 00a smaller, thereby increasing the PPI of the array substrate 000.

In the embodiments of the present disclosure, each active pattern 300 further includes a channel area 303 disposed between the first conductive section 301 and the second conductive section 302. Since there are two second conductive sections 302 in the active pattern 300, two channel areas 303 are contained in the active pattern 300. The two channel areas 303 in the active pattern 300 correspond to two different gate lines 500, and an orthographic projection of each channel area 303 in the active layer 400 on the substrate 100 overlaps an orthographic projection of the corresponding gate line 500 on the substrate 100. Exemplarily, the orthographic projection of each channel area 300 on the substrate 100 is disposed within the orthographic projection of the corresponding gate line 500 on the substrate 100.

The active pattern 300, a part of the data line 200 electrically connected to the first conductive section 301 of the active pattern 300, a part of a pixel electrode 400 electrically connected to the second conductive section 302 of the active pattern 300, and a part of a gate line 500 overlapping with the channel area 303 together form a transistor (also known as a TFT). That is, a gate of the transistor corresponds to the gate line 500, a first pole of the transistor is electrically connected to the data line 200, and a second pole of the transistor is electrically connected to the pixel electrode 400. The first pole of the transistor is the source or the drain, and the second pole of the transistor is another one. In this way, the electrical signal loaded on the data line 200 may be transmitted to the pixel electrode 400 in the case that the transistor is turned on by the gate drive signal applied to the gate line 500, so that a pixel voltage is applied to the pixel electrode 400.

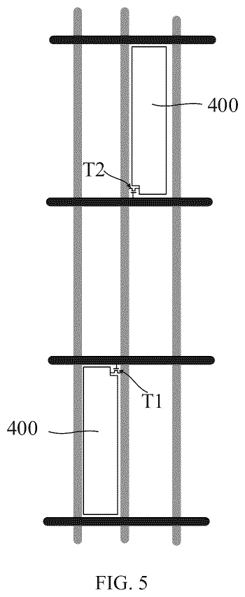

Since one active pattern 300 includes one first conductive section 301, two second conductive sections 302, and two channel areas 303, and the one first conductive section 301 is electrically connected to one data line 200, the two second conductive sections 302 are electrically connected to two different pixel electrodes 400, and the two channel areas 303 overlap two different gate lines 500. Thus, the data line 200 is connected, at one location in the data line 200, to the first poles in two different transistors. In some embodiments, referring to FIG. 5, which is a simplified schematic diagram of the array substrate shown in FIG. 3, the active layer in transistor Tl and transistor T2 is the same structure, i.e., the active layers in transistor T1 and transistor T2 are the same one active pattern 300. The first poles in transistor T1 and transistor T2 are electrically connected to the same data line 200 at the same location, for example, the data line 200 is electrically connected to the first conductive section 301 in the active pattern 300, such that the first poles in the transistor T1 and the transistor T2 are connected to one data line 200 at the same time. The second poles in the transistor TI and the transistor T2 are electrically connected to two different pixel electrodes 400, respectively, and the gate electrodes in the transistor T1 and the transistor T2 are electrically connected to two different gate lines 500, respectively. In this way, the two different transistors are respectively turned on under the control of two different gate lines 500, such that the same data line 200 can charge two different pixel electrodes 400 in a time-sharing manner. That is, both of the two different pixel electrodes 400 are capable of being individually loaded with pixel voltage. In the array substrate 000, every two transistors are connected to the same data line 200 through the via holes for connecting the first conductive section 301 to the data line 200, which effectively reduces the number of via holes for connecting the first conductive section 301 to the data line 200 in the array substrate 000, ensuring that the number of the via holes does not limit the size of the sub-pixel region 00a, such that the size of the sub-pixel region 00a is further reduced, thereby further increasing the PPI of the array substrate 000.

It should be noted that the size of the sub-pixel region 00a in the embodiments of the present disclosure means the width of the sub-pixel region 00a in the first direction X and the width of the sub-pixel region 00a in the second direction Y. The smaller size of the sub-pixel region 00a in the embodiments of the present disclosure means a smaller width of the sub-pixel region 00a in the first direction X and a smaller width of the sub-pixel region 00a in the second direction Y.

In summary, the array substrate according to some embodiments of the present disclosure includes a substrate, multiple data lines, multiple active patterns, and multiple pixel electrodes. The data line is disposed on a side, proximate to the substrate, of the active pattern, and the pixel electrode is located on a side, distal to the substrate, of the active pattern. Therefore, the first conductive section in the active pattern is connected to the data line through a via hole on the side proximate to the substrate, and the second conductive section in the active pattern is connected to the pixel electrode through a via hole on the side distal to the substrate. That is, the via holes for connecting the first conductive section to the data line and the via holes for connecting the pixel electrode to the second conductive section are provided on the two opposite sides of the active pattern in the array substrate. In this way, even if the horizontal distance between the via hole for connecting the first conductive section to the data line and the via hole for connecting the pixel electrode to the second conductive section is small due to the small size of the sub-pixel region, it can be ensured that the two via holes are not connected, thereby avoiding the short-circuit between the data line and the pixel electrode. Further, it can be ensured that the size of the sub-pixel region in the array substrate is no longer affected by the horizontal distance between the two via holes, which makes the size of the sub-pixel region smaller, thereby increasing the PPI of the array substrate. In addition, every two transistors in the array substrate are connected to the same data line through the via holes for connecting the first conductive section to the data line, which effectively reduces the number of via holes for connecting the first conductive section to the data line in the array substrate, ensuring that the number of the via holes does not limit the size of the sub-pixel region, such that the size of the sub-pixel region is further reduced, thereby further increasing the PPI of the array substrate.

In some embodiments, as shown in FIG. 3, two gate lines 500 corresponding to two channel areas 303 in the active pattern 300 are disposed adjacent to each other in the array substrate 000. That is, for the two adjacent gate lines 500 in the array substrate 000, one gate line 500 is overlapped with one channel area 303 in the active pattern 300, and the other gate line 500 is overlapped with another channel area 303 in the active pattern 300. In this way, it can be ensured that the active pattern 300, serving as the active layer in two different transistors, has a smaller width in the second direction Y, which is more advantageous for the miniaturization of the sub-pixel region 00a.

In the embodiments of the present disclosure, as shown in FIG. 3, the two second conductive sections 302 in each active pattern 300 are disposed on both sides of the corresponding data line 200 in the first direction X and on both outer sides of the two gate lines 500 corresponding to the two channel areas 303 in the active pattern 300 in the second direction Y. That is, the two second conductive sections 301 in the active pattern 300 are connected to two different pixel electrodes 400, and the via holes provided in the array substrate 000 (which are used for connecting the second conductive sections 301 to the pixel electrodes 400) are distributed in the side, distal to the substrate 100, of the active pattern 300. Even if the size of the sub-pixel region 00a in the array substrate 000 is small, the distance between the via hole for connecting one second conductive section 301 to one pixel electrode 400 and the via hole for connecting another second conductive section 301 to another pixel electrode 400 is large to ensure that the two via holes do not be connected.

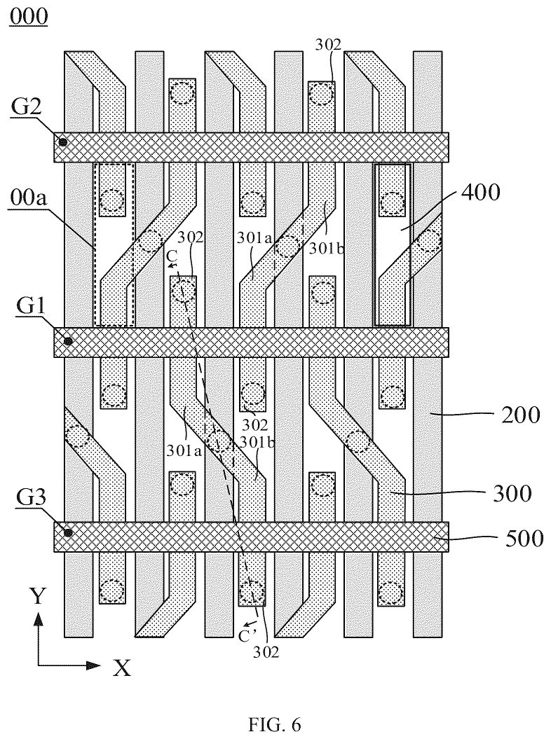

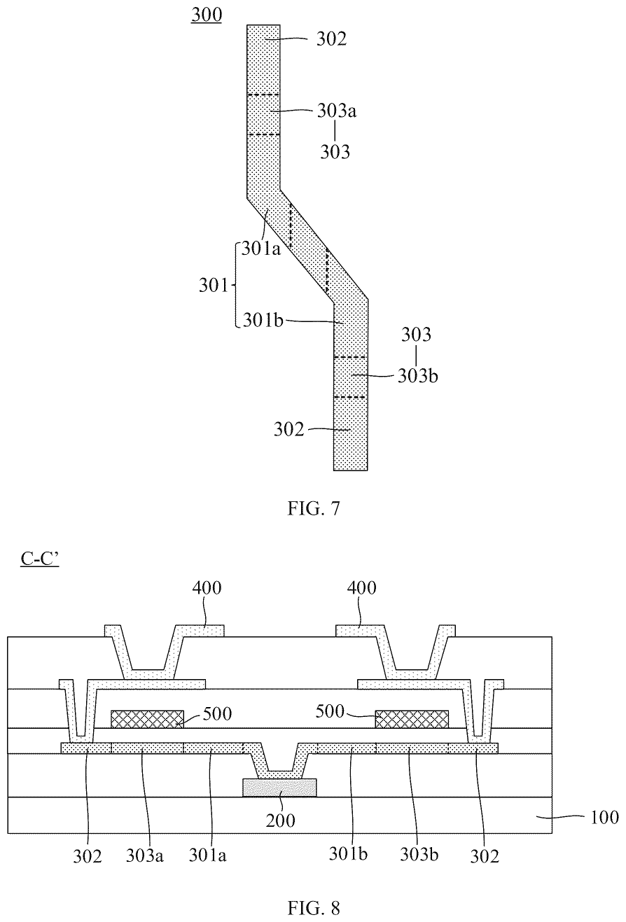

In some embodiments, as shown in FIG. 6 and FIG. 7, FIG. 6 is a top view of another array substrate according to some embodiments of the present disclosure, and FIG. 7 is a partially enlarged view of a single active pattern in the array substrate illustrated in FIG. 6. The first conductive section 301 in each active pattern 300 may include: a first portion 301a disposed on one side of the data line 200 corresponding to the active pattern 300, and a second portion 301b disposed on the other side of the data line 301b. Here, the part of the first conductive section 301 disposed between the first portion 301a and the second portion 301b is overlapped with the data line 200 and is electrically connected to the data line 200 corresponding to the active pattern 300. It should be noted that in FIG. 6, the part of the first conductive section 301 of the active pattern 300 located on the left side of the corresponding data line 200 is the first portion 301a, and the part of the first conductive section 301 of the active pattern 300 located on the right side of the corresponding data line 200 is the second portion 301b.

In the present disclosure, for two adjacent columns of active patterns 300 in the array substrate 000, multiple first portions 301a in one column of active patterns 300 and multiple second portions 301b in the other column of active patterns 300 are disposed between two adjacent data lines 200, and the two adjacent data lines 200 are electrically connected to the first conductive sections 301 in the two columns of active patterns, respectively. The multiple first portions 301a in one column of active patterns 300 and the multiple second portions 301b in the other column of active patterns 300 are alternately arranged. That is, each of the first portions 301a in one column of the active patterns 300 is disposed between two adjacent second portions 301b in another column of the active patterns 300, and each of the second portions 301b in another column of the active patterns 300 is disposed between two adjacent first portions 301a in one column of the active patterns 300.

Since two second conductive sections 302 in the active pattern 300 are disposed on both sides of the first conductive section 301, and the two second conductive sections 302 are disposed adjacent to the first portion 301a and the second portion 301b in the first conductive section 301. Thus, in the same active pattern 300, the first portion 301a of the first conductive section 301 and the second conductive section 302 adjacent to the first portion 30la may be disposed within two adjacent sub-pixel regions 00a, respectively, and the second portion 301b of the first conductive section 301 and the second conductive section 302 adjacent to the second portion 301b may be disposed within other two sub-pixel regions 00a, and the same one sub-pixel region 00a is provide with the first portion 301a or the second portion 301b in one active pattern 300 and the second conductive section 302 in the other active pattern 300, such that the pixel electrode 400 disposed in the sub-pixel region 00a is electrically connected to the second conductive section 302 in the sub-pixel region 00a.

In some embodiments of the present disclosure, as shown in FIGS. 7 and 8, FIG. 8 is a schematic structural diagram of film layers of the array substrate illustrated in FIG. 6 along a tangent line C-C′, the two channel areas 303 in each of the active patterns 300 include a first channel area 303a disposed adjacent to the first portion 301a and a second channel area 303b disposed adjacent to the second portion 301b. For each active pattern 300, the first channel area 303a is disposed between the first portion 301a of the first conductive section 301 and the second conductive section 302 adjacent to the first portion 301a, and the second channel area 302b is disposed between the second portion 301b of the first conductive section 301 and the second conductive section 302 adjacent to the second portion 301b.

In the present disclosure, in two adjacent rows of active patterns 300 in the array substrate 000, multiple first channel areas 303a in one row of active patterns 300 are alternately arranged with multiple first channel areas 303a in the other row of active patterns 300, and the multiple first channel areas 303a in one row of active patterns 300 and the multiple first channel areas 303a in the other row of active patterns 300 303a are all overlapped with the same first gate line G1. The first gate line G1 is one of the multiple gate lines 500.

According to the above case, the multiple first portions 301a in one column of active patterns 300 are alternately arranged with the multiple second portions 301a in the other column of active patterns 300, the multiple first channel areas 303a in one row of active patterns 300 are alternately arranged with the multiple first channel areas 303b in the other row of active patterns 300, and the multiple first channel areas 303a in one row of active patterns 300 and the multiple first channel areas 303b in the other row of active patterns 300 are all overlapped with the same first gate line G1, it can be ensured that two transistors in the array substrate 000 are neither connected to the same gate line 500 nor the same data line 200, thereby ensuring that the on and off of each transistor in the array substrate are controlled separately.

In some embodiments, for the two adjacent rows of active patterns 300 in the array substrate 000, the multiple second channel areas 303b in one row of active patterns 300 all overlap the same second gate line G2, and the multiple second channel areas 303b in the other row of active patterns 300 all overlap the same third gate line G3. Wherein, the second gate line G2 is a gate line of the multiple gate lines 500 located on one side of the first gate line G1, and the third gate line G3 is a gate line of the multiple gate lines 500 located on the other side of the first gate line G1. In this way, it can be ensured that a second conductive section 302 exists within each sub-pixel region 00a of the array substrate 000, such that pixel electrode 400 electrically connected to the second conductive section 302 is disposed in each sub-pixel region 00a. Further, each pixel electrode 400 in the array substrate 000 is accessed with a corresponding transistor in the corresponding sub-pixel region 00a.

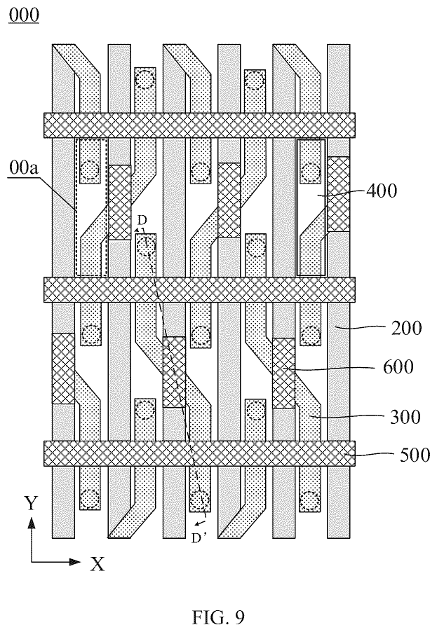

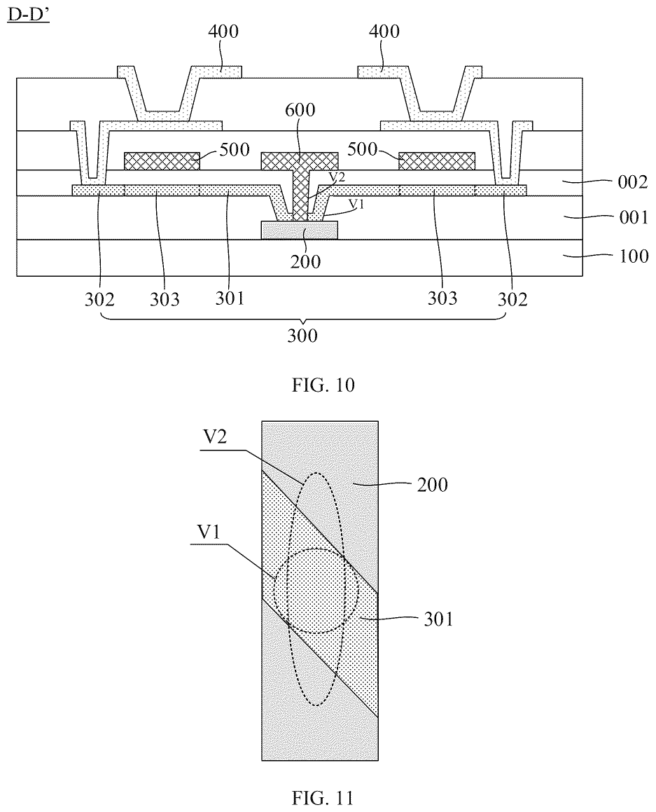

In some embodiments, referring to FIGS. 9 and 10, FIG. 9 is a top view of yet another array substrate according to some embodiments of the present disclosure, and FIG. 10 is a schematic structural diagram of film layers of the array substrate illustrated in FIG. 9 along a tangent line D-D′. The array substrate 000 may further include multiple auxiliary electrodes 600 disposed on a side, distal to the substrate 100, of the multiple active patterns 300. The multiple auxiliary electrodes 600 in the array substrate 000 are in one-to-one correspondence with the multiple active patterns 300, and the first conductive section 301 in each of the active patterns 300 is electrically connected to a corresponding data line 200 via a corresponding auxiliary electrode 600.

In some embodiments of the present disclosure, the multiple gate lines 500 in the array substrate 000 are disposed on a side, distal to the substrate 100, of the multiple active patterns 300. In the preparation process of the array substrate 000, after the multiple gate lines 500 are prepared, it is necessary to conductivize the multiple active patterns 300 using the multiple gate lines 500 as a mask, so that a part of the active pattern 300 that is not covered by the gate lines 500 is conductivized to form the first conductive section 301 and the second conductive section 302 in the active pattern 300, and the part of the active pattern 300 that is covered by the gate lines 500 are not conductivized may serve as the channel area 303.

Since the first conductive section 301 in the active pattern 300 is electrically connected to the corresponding data line 200 through the via hole, and in the process of conductivizing the active pattern 300, it is less effective to conductivize the part of the active pattern that is located in the via hole, which results in a higher resistance of the first conductive section 301 formed in the via hole. Therefore, in order to improve the connection between the first conductive section 301 in the active pattern 300 and the corresponding data line 200, the auxiliary electrode 600 having a smaller resistance may be provided within the array substrate 000, and the data line 200 is connected to the first conductive section 301 via the auxiliary electrode 600. In this way, a better connection between the data line 200 and the first conductive section 301 is made in the case that the data line 200 is electrically connected to the first conductive section 301 via the auxiliary electrode 600 having the smaller resistance.

In the present disclosure, the multiple auxiliary electrodes 600 in the array substrate 000 may be provided in the same layer and of the same material as the multiple gate lines 500. That is, the multiple auxiliary electrodes 600 and the multiple gate lines 500 are formed using one-time patterning process. The one-time patterning process includes: coating a photoresist, exposing, developing, etching, and removing the photoresist. In this way, the multiple auxiliary electrodes 600 are formed synchronously during the process of forming the multiple gate lines 500 on the array substrate 000, effectively reducing the difficulty of preparing the array substrate 000.

In some embodiments, the array substrate 000 further includes a first interlayer dielectric layer 001 and a gate insulation layer 002. The first interlayer dielectric layer 001 is disposed on a side of the multiple data lines 200 distal to the substrate 100, and the multiple active patterns 300 are disposed on a side of the first interlayer dielectric layer 001 distal to the substrate 100. That is, the first interlayer dielectric layer 001 is disposed between the multiple data lines 200 and the multiple active patterns 300 in the direction perpendicular to the substrate 100. The gate insulation layer 002 is disposed on a side of the multiple active patterns 300 distal to the substrate 100, and the multiple gate lines 500 and the multiple auxiliary electrodes 600 are all disposed on a side of the gate insulation layer 002 distal to the substrate 100. That is, the gate insulation layer 002 is disposed between the multiple active patterns 300 and the multiple gate lines 500 in the direction perpendicular to the substrate 100, such that the gate lines 500 are insulated from the active pattern 300 by the gate insulation layer 002.

The array substrate 000 is provided with a first via hole V1 penetrating through the first interlayer dielectric layer 001 and a second via hole V2 penetrating through the gate insulation layer 002 and the first interlayer dielectric layer 001, the first conductive section 301 in the active pattern 300 is connected to the data line 200 through the first via hole V1 and the auxiliary electrode 600 is connected to the data line 200 and the first conductive section 301 in the active pattern 300 through the second via hole V2.

Exemplarily, an orthographic projection of the first via hole V1 on the substrate 100 falls within an orthographic projection of the first conductive section 301 in the active pattern 300 on the substrate 100, and falls within an orthographic projection of the data line 200 on the substrate 100. The orthographic projection of the second via hole V2 on the substrate 100 falls within the orthographic projection of the data line 200 on the substrate 100, and there is a part of the orthographic projection of the second via hole V2 on the substrate 100 that is located outside the orthographic projection of the first conductive section 301 on the substrate 100. Referring to FIG. 11, FIG. 11 is a partially enlarged view of a first via hole and a second via hole according to some embodiments of the present disclosure, a part of the orthographic projection of the second via hole V2 on the substrate 100 is located within the orthographic projection of the first via hole V1 on the substrate 100, and the other part of the orthographic projection of the second via hole V2 on the substrate 100 is located outside the orthographic projection of the first via hole V1 on the substrate 100. It should be noted that, FIG. 11 is illustrated as an example of a situation in which the orthographic projection of the first via hole V1 on the substrate 100 also exists outside the orthographic projection of the second via hole V2 on the substrate 100, and in some other embodiments, the orthographic projection of the first via hole V1 on the substrate 100 may also be located wholly within the orthographic projection of the second via hole V2 on the substrate 100, but it is necessary to ensure that the orthographic projection of the first via hole V1 on the substrate 100 and the orthographic projection of the second via hole V2 on the substrate 100 are separated by a certain distance.

The part of the auxiliary electrode 600 disposed within the second via hole V2 is connected to both the first conductive section 301 and the data line 200. For example, the auxiliary electrode 600 is connected to the first conductive section 301 in a region where the second via hole V2 intersects the first via hole V1, and the auxiliary electrode 600 is connected to the data line 200 in a region of the second via hole V2 that is located outside the first via hole V1.

It should be noted that after the gate insulation layer 002 is prepared during the preparation process in the array substrate 000, it is necessary to pattern the gate insulation layer 002 to form the second via hole V2 in the gate insulation layer 002, and after the second via hole V2 is formed, the part of the active pattern 300 disposed within the second via hole V2 may be conductivized. In this way, even if the auxiliary electrode 600 provided in the same layer as the gate line 500 may affect the conductivization effect of the part of the active pattern 300, it can be ensured that the part of the active pattern 300 disposed within the second via hole V2 is conductivized.

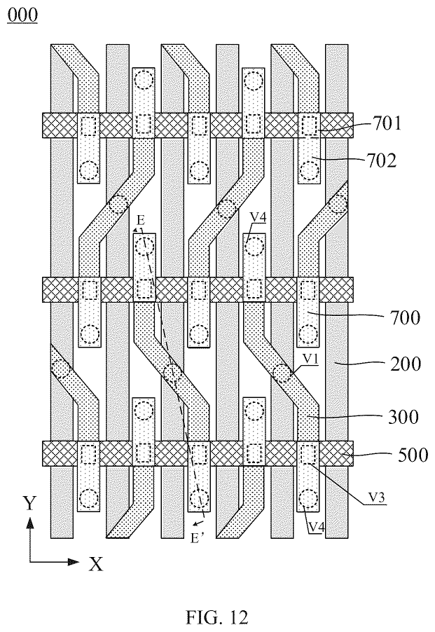

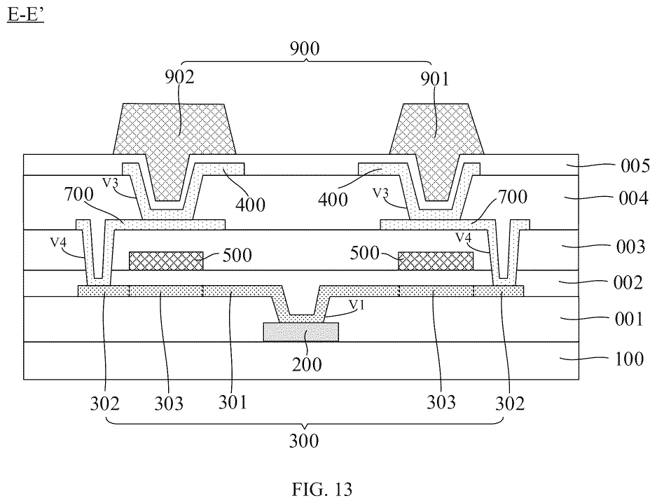

In the embodiments of the present disclosure, referring to FIG. 12 and FIG. 13, FIG. 12 is a top view of a still yet another array substrate according to some embodiments of the present disclosure, and FIG. 13 is a schematic structural diagram of film layers of the array substrate illustrated in FIG. 12 along a tangent line E-E′. The array substrate 000 further includes: multiple transfer electrodes 700 in one-to-one correspondence with the multiple pixel electrodes 400. The multiple transfer electrodes 700 may be disposed between the multiple active patterns 300 and the multiple pixel electrodes 400 in the direction perpendicular to the substrate 100, and each pixel electrode 400 may be electrically connected to the second conductive section 302 in the active pattern 300 via the corresponding transfer electrode 700.

In the present disclosure, both the second conductive section 302 in one active pattern 300 and the first portion 301a or the second portion 301b in the other active pattern 300 are disposed within the same sub-pixel region 00a, and the pixel electrode 400 disposed within the sub-pixel region 00a is only electrically connected to the second conductive section 302. As a result, the pixel electrode 400 will have an overlapping region with the active layer in the other transistor (i.e., the first portion 301a or the second portion 302b in the other active pattern 300), which leads to a parasitic capacitance between the two. In order to reduce the effect of the parasitic capacitance on the pixel voltage loaded on the pixel electrode 400, it is necessary to increase the distance between the pixel electrode 400 and the active pattern 300. Further, the pixel electrode 400 is electrically connected to the first conductive section 301 in the active pattern 300 via the transfer electrode 700.

At least a part of the orthographic projection of the transfer electrode 700 on the substrate 100 may be disposed within the sub-pixel region 00a in the array substrate 000, and the orthographic projection of the transfer electrode 700 on the substrate 100 may overlap the orthographic projection of the second conductive section 302 in the one active pattern 300 disposed within the sub-pixel region 00a on the substrate 100, and may not overlap the orthographic projection of the first portion 301a or the second portion 301b of the other active pattern 300 on the substrate 100. In this way, the parasitic capacitance will not be generated between the auxiliary electrode 600 and the first portion 301a or the second portion 301b in the other active pattern 300 in the sub-pixel region 00a, and the parasitic capacitance generated between the pixel electrodes 400 and the first portion 301a or the second portion 301b in another active pattern 300 in the sub-pixel region 00a has a smaller influence on the pixel voltage loaded on the pixel electrodes 400 due to the larger distance therebetween.

In some embodiments of the present disclosure, since a part of the transfer electrode 700 is provided within the sub-pixel region 00a, in order to ensure that the pixel electrodes 400 disposed within the sub-pixel region 00a do not affect the opening rate of the sub-pixel region 00a, the transfer electrodes 700 are made of a transparent conductive material. That is, the transfer electrodes 700 are transparent electrodes. In addition, the active pattern 300 in the array substrate 000 is also made of a light-transmissive semiconductor material, for example, the active pattern 300 is made of an oxide semiconductor material. In this way, the larger area of the active pattern 300 in the sub-pixel region 00a does not affect the opening rate of the sub-pixel region 00a, which in turn makes the opening rate of the array substrate 000 higher.

In some embodiments, the array substrate 000 further includes a second interlayer dielectric layer 003 and a planarization layer 004. The second interlayer dielectric layer 003 is disposed on a side of the multiple gate lines 500 distal to the substrate 100, and the multiple transfer electrodes 700 are disposed on a side of the second interlayer dielectric layer 003 distal to the substrate 100. That is, the second interlayer dielectric layer 003 is disposed between the multiple gate lines 500 and the multiple transfer electrodes 700 in the direction perpendicular to the substrate 100. The planarization layer 004 is disposed on a side of the multiple transfer electrodes 700 distal to the substrate 100, and the multiple pixel electrodes 400 are disposed on a side of the planarization layer 004 distal to the substrate 100. That is, the planarization layer 004 is disposed between the multiple transfer electrodes 700 and the multiple pixel electrodes 400 in the direction perpendicular to the substrate 100. In this way, a gate insulating layer 002, a second interlayer dielectric layer 003, and a planarization layer 004 are disposed between the pixel electrode 400 and the active layer pattern 300, such that a distance therebetween is larger.

The array substrate 000 is also provided with a third via hole V3 penetrating through the planarization layer 004 and a fourth via hole V4 penetrating through the second interlayer dielectric layer 003 and the gate insulation layer 002. The pixel electrode 400 is connected to the transfer electrode 700 through the third via hole V3, and the transfer electrode 700 is connected to the second conductive section 302 in the active pattern 300 through the fourth via hole V4.

In some embodiments of the present disclosure, the transfer electrode 700 in the array substrate 000 includes a first adapter sub-electrode 701 and a second adapter sub-electrode 702 connected to each other. The orthographic projection of the first adapter sub-electrode 701 on the substrate 100 is located within the orthographic projection of the gate line 500 on the substrate 100, the orthographic projection of the second adapter sub-electrode 702 on the substrate 100 is located outside the orthographic projection of the gate line 500 on the substrate 100, and the orthographic projection of the second adapter sub-electrode 702 on the substrate 100 is located within the sub-pixel region 00a.

The orthographic projection of the fourth via hole V4 on the substrate 100 overlaps the orthographic projection of the second adapter sub-electrode 702 on the substrate 100. For example, the orthographic projection of the fourth via hole V4 on the substrate 100 is located within the orthographic projection of the second adapter sub-electrode 702 on the substrate 100, such that the second conductive section 302 is connected to the second adapter sub-electrode 702 through the fourth via hole V4.

The orthographic projection of the third via hole V3 on the substrate 100 overlaps the orthographic projection of the first adapter sub-electrode 701 on the substrate 100. For example, the orthographic projection of the third via hole V3 on the substrate 100 is located within the orthographic projection of the first adapter sub-electrode 701 on the substrate 100. To this end, the orthographic projection of the third via V3 on the substrate 100 may be located within the orthographic projection of the gate 500 on the substrate 100. Since the third via hole V3 is disposed within the planarization layer 004, the planarization of the side of the planarization layer 004 distal to the substrate 100 is poor at the position of the third via V3. After the array substrate 000 is assembled in the liquid crystal display panel, the liquid crystal molecules in the liquid crystal display panel is disposed in the side of the planarization layer 004 distal to the substrate 100, and in the case that the planarization in the side of the planarization layer 004 distal to the substrate 100 is poor at the position of the third via V3, the liquid crystal molecules in the liquid crystal display panel may be collected at the position of the third via hole V3, resulting in poor optical effect at the position of the third via hole V3 in the planarization layer 004. For this reason, the orthographic projection of the third via hole V3 on the substrate 100 is located within the orthographic projection of the gate line 500 on the substrate 100 in the embodiments of the present disclosure, such that the gate line 500 can shield the light emitted from the position of the third via hole V3, such that the light is not emitted from the liquid crystal display panel, thereby ensuring a better display effect of the liquid crystal display panel.

In some embodiments, the array substrate 000 further includes a passivation layer 005 disposed on a side of the multiple pixel electrodes 400 distal to the substrate 100, and a support layer 900 disposed on a side of the passivation layer 005 distal to the substrate 100. A part of the support layer 900 may be filled in the third via hole V3 of the array substrate 000, and another part of the support layer 900 may protrude relative to the passivation layer 005 away from the substrate 100. The third via hole V3 in the array substrate 000 is filled by the support layer 900, such that after the array substrate 000 is integrated within the liquid crystal display panel 000, the liquid crystal molecules in the liquid crystal display panel is not collected within the third via hole V3, thereby improving the optical effect at the location of the third via hole V3. Moreover, there is also a part of the support layer 900 protruding from the side of the passivation layer 005 away from the substrate 100, and this part of the support layer 900 can support the color filter substrate in the liquid crystal display panel.

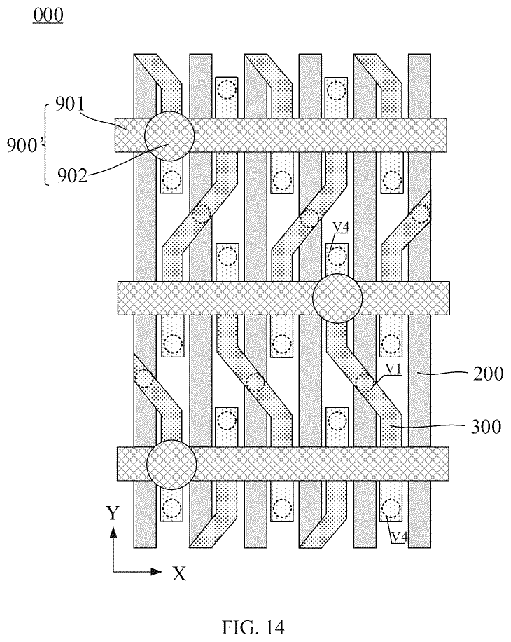

In the present disclosure, referring to FIG. 14, FIG. 14 is a top view of an array substrate according to some embodiments of the present disclosure. The support layer 900 in the array substrate 000 includes: multiple support strips 900′, and the multiple support strips 900′ are in one-to-one correspondence with multiple gate lines 500, and an orthographic projection of each support strip 900′ on the substrate 100 may cover the orthographic projection of a corresponding gate line 500 on the substrate 100. Since the orthographic projection of the third via hole V3 in the array substrate 000 on the substrate 100 is located within the orthographic projection of the gate line 500 on the substrate 100, when the orthographic projection of the support strip 900′ on the substrate 100 covers the orthographic projection of the corresponding gate line 500 on the substrate 100, it can be ensured that the support strip 900′ fills and levels up each third via hole V3 overlapped with the gate line 500.

In addition, in the case that the support layer 900 is provided with columnar support structures corresponding to each of the third via holes V3, the size of these columnar support structures may be small due to the high PPI of the array substrate 000 and the small size of the sub-pixel region 00a in the array substrate 000 in the present disclosure, which results in a poorer effect for supporting the color filter substrate in the liquid crystal display panel. In the present disclosure, by providing that the support layer 900 is constructed with the support strip 900′, the support strip 900′ not only fills in each of the third via holes V3 overlapping with the gate lines 500, but also provides stable support for the color filter substrate in the liquid crystal display panel 000 due to the larger size of the support strip 900′.

In some embodiments, each support bar 900′may include multiple support bar bodies 901, and support posts 902 disposed between two adjacent support bar bodies 901. The multiple support bar bodies 901 are disposed in sequence along the first direction X, and the support post 902 between two adjacent support bar bodies 901 may be fixedly connected to the two support bar bodies 901.

In the arrangement direction of the multiple gate lines 500, i.e., in the second direction Y, the width of the support column 902 is larger than the width of the support bar body 901. In this way, after the array substrate 000 is integrated within the liquid crystal display panel, the effect of supporting the color filter substrate in the liquid crystal display panel can be further improved by the support bar 902 with a larger size.

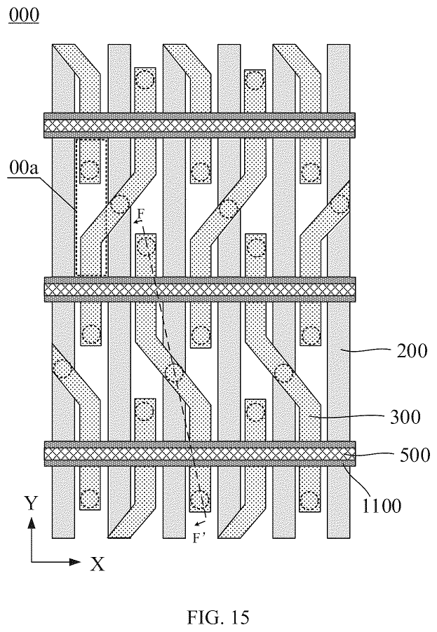

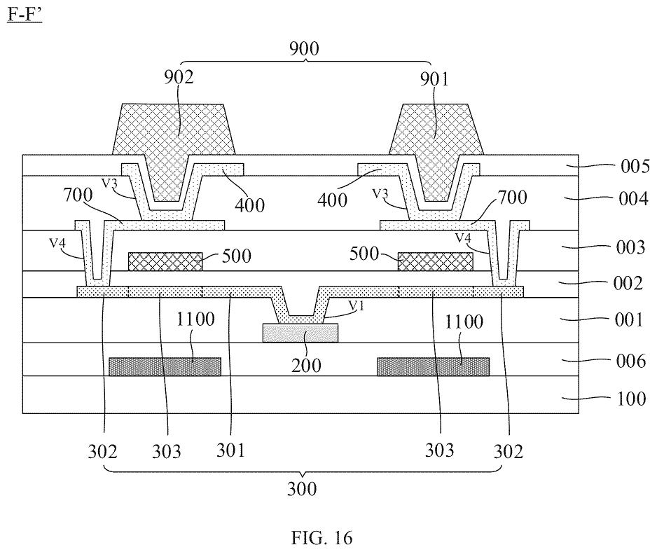

In some embodiments, referring to FIG. 15 and FIG. 16, FIG. 15 is a top view of another array substrate according to some embodiments of the present disclosure, and FIG. 16 is a schematic structural diagram of film layers of the array substrate illustrated in FIG. 15 along a tangent line F-F′. The array substrate 000 further includes multiple auxiliary shading strips 1100 disposed on a side of the multiple active patterns 300 proximate to the substrate 100. The multiple auxiliary shading strips 1100 may be in one-to-one correspondence with the multiple gate lines 500, an orthographic projection of each of the auxiliary shading strips 1100 on the substrate 100 may cover the orthographic projection of the corresponding gate line 500 on the substrate 100, and the orthographic projection of the channel area 303 in active pattern 300 on the substrate 100 is located within the orthographic projection of the auxiliary shading strips 1100 on the substrate 100 Since the channel area 303 in the active pattern 300 is more sensitive to light, carriers may be generated within the channel area 303 when light irradiates the channel area 303 in the active pattern 300, and thus leakage currents may further be generated within the channel area 303, resulting in poorer electrical performance of the transistors in the array substrate 000. For this reason, multiple auxiliary shading strips 1100 are provided on a side of the multiple active patterns 300 proximate to the substrate 100 in the array substrate 000, and the auxiliary shading strips 1100 cover the channel areas 303 in the active patterns 300, the channel areas 303 in the active patterns 300 can be shielded by the auxiliary shading strips 1100, the light emitted from the backlight module in the display device that is directed to the channel area 303 can be blocked by the auxiliary shading strip 1100 after the array substrate 000 is assembled in a display device, thereby ensuring that the transistors within the array substrate 000 have a better electrical performance.

Exemplarily, the multiple auxiliary shading strips 1100 may be closer to the substrate 100 with respect to the multiple data lines 200 in the direction perpendicular to the substrate 100. The array substrate 000 may further include: a buffer layer 006. The multiple auxiliary shading strips 1100 may be disposed on a side of the substrate 100, the buffer layer 006 may be disposed on a side of the multiple auxiliary shading strips 1100 distal to the substrate 100, and the multiple data lines 200 may be disposed on a side of the buffer layer 006 distal to the substrate 100.

It should be noted that since the auxiliary shading strips 1100 cover the gate lines 500, the width of the auxiliary shading strip 1100 is greater than the width of the gate line 500. In this case, any two adjacent auxiliary shading strips 1100 and any two adjacent data lines 200 can enclose one sub-pixel region 00a. It should be further noted that when the active pattern 300 in the array substrate 000 is made of semiconductor material with better optical stability, even if the light is irradiated on the channel area 303 in the active pattern 300, it can be ensured that no carriers will be generated in the channel area 303, and thereby ensure that no leakage current is generated in the channel area 303. In this case, there is no need to provide auxiliary shading strips within the array substrate 000, which makes the opening ratio of the sub-pixel region 00a in the array substrate 000 larger.

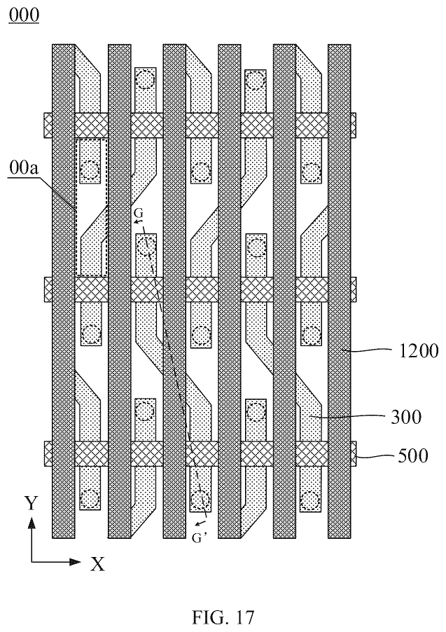

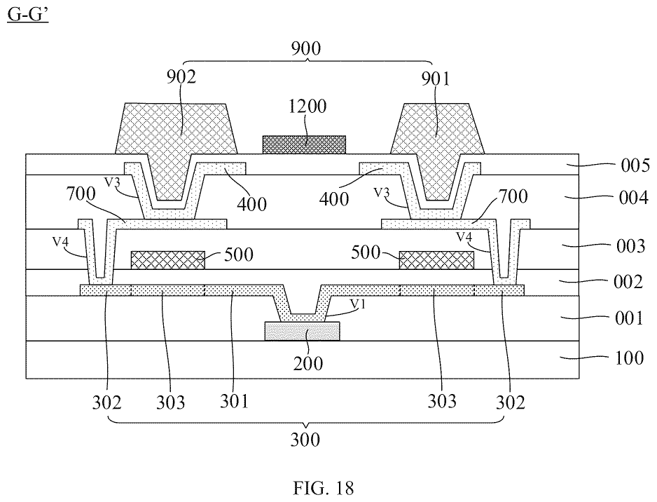

In some embodiments, referring to FIG. 17 and FIG. 18, FIG. 17 is a top view of an array substrate according to some embodiments of the present disclosure, and FIG. 18 is a schematic structural diagram of film layers of the array substrate illustrated in FIG. 17 along a tangent line G-G′. The array substrate 000 includes multiple common electrode strips 1200 disposed on a side of the multiple pixel electrodes 400 distal to the substrate 100. Exemplarily, the multiple common electrode strips 1200 may all be distributed on the side of the planarization layer 004 distal to the substrate 100 in the array substrate 000. Each of the common electrode strips 1200 in the array substrate 000 has a light-shielding property, and the multiple common electrode strips 1200 in the array substrate 000 are in one-to-one correspondence with the multiple data lines 200, and an orthographic projection of each of the common electrode strips 1200 on the substrate 100 may cover an orthographic projection of corresponding data line 200 on the substrate 100.

In this case, the common electrode strip 1200 in the array substrate 000 is not only capable of cooperating with the pixel electrodes 400 to generate a voltage difference for driving liquid crystal molecules in the liquid crystal display panel, but also capable of shading a part of the light rays emitted from the different sub-pixel regions 00a due to the light-shielding property of the common electrode strips 1200. Exemplarily, for two sub-pixel regions 00a distributed adjacent to each other in the first direction X, the light rays emitted from one sub-pixel region 00a to another sub-pixel region 00a may be blocked by the common electrode strip 1200, so that the light rays emitted from one sub-pixel region 00a cannot be directed to another sub-pixel region 00a, thereby preventing the liquid crystal display panel integrated with the array substrate 000 from poor crosstalk.

It should be noted that a sub-pixel needs to be provided in each sub-pixel region 00a in the array substrate 000, the sub-pixel may include a pixel electrode 400 disposed within the sub-pixel region 00a, and a transistor electrically connected to the pixel electrode 400. The types of sub-pixels in each column of sub-pixels in the array substrate 000 are the same, while the types of sub-pixels in two adjacent columns in the array substrate 000 are different. For example, the sub-pixels in each column of subpixels of the array substrate 000 may be red sub-pixels, green sub-pixels, or blue sub-pixels, and a column of red sub-pixels, a column of green sub-pixels, and a column of blue sub-pixels may be arranged adjacent to each other within the array substrate 000.

In the case that multiple common electrode strips 1200 are provided within the array substrate 000, the width of each common electrode strip 1200 may be greater than or equal to the width of each data line 200 because the common electrode strip 1200 needs to cover the data line 200. In this case, any two adjacent common electrode strips 1200 and any two adjacent gate lines 500 can enclose a sub-pixel region 00a. In this way, for two sub-pixels disposed adjacent to each other in the first direction X, the light rays exiting from one sub-pixel will not be directed to the other sub-pixel by providing the common electrode strips 1200, so as to ensure that the liquid crystal display panel will not suffer from the color crosstalk. For two sub-pixels disposed adjacent to each other in the second direction Y, even if the light emitted from one sub-pixel is emitted to the other sub-pixel, the color crosstalk of the liquid crystal display panel can be avoided because the types of the two sub-pixels are the same.

In some embodiments, the common electrode strip 1200 in the array substrate 000 is made of a conductive material having light-reflecting property, for example, a metallic material, such that light rays directed to the common electrode strip 1200 may be reflected by the common electrode strip 1200.

In some other embodiments, the common electrode strip 1200 in the array substrate 000 is made of a conductive material having light-absorbing properties, for example, a black metallic material, so that the light rays emitted to the common electrode strip 1200 can be absorbed by the common electrode strip 1200. The common electrode strip 1200 not only ensures that the light rays emitted from one sub-pixel are not emitted to the other sub-pixel in the two adjacent sub-pixels in the first direction X, but also ensures that the ambient light emitted to the array substrate 000 is also absorbed by the common electrode strip 1200, thereby reducing the reflectivity of the liquid crystal display panel integrated with the array substrate 000.

In summary, the array substrate according to some embodiments of the present disclosure includes a substrate, multiple data lines, multiple active patterns, and multiple pixel electrodes. The data line is disposed on a side, proximate to the substrate, of the active pattern, and the pixel electrode is located on a side, distal to the substrate, of the active pattern. Therefore, the first conductive section in the active pattern is connected to the data line through a via hole on the side proximate to the substrate, and the second conductive section in the active pattern is connected to the pixel electrode through a via hole on the side distal to the substrate. That is, the via holes for connecting the first conductive section to the data line and the via holes for connecting the pixel electrode to the second conductive section are provided on the two opposite sides of the active pattern in the array substrate. In this way, even if the horizontal distance between the via hole for connecting the first conductive section to the data line and the via hole for connecting the pixel electrode to the second conductive section is small due to the small size of the sub-pixel region, it can be ensured that the two via holes are not connected, thereby avoiding the short-circuit between the data line and the pixel electrode. Further, it can be ensured that the size of the sub-pixel region in the array substrate is no longer affected by the horizontal distance between the two via holes, which makes the size of the sub-pixel region smaller, thereby increasing the PPI of the array substrate. In addition, every two transistors in the array substrate are connected to the same data line through the via holes for connecting the first conductive section to the data line, which effectively reduces the number of via holes for connecting the first conductive section to the data line in the array substrate, ensuring that the number of the via holes does not limit the size of the sub-pixel region, such that the size of the sub-pixel region is further reduced, thereby further increasing the PPI of the array substrate.

Embodiments of the present disclosure also provide a method for manufacturing the array substrate in the above embodiments. The method may include the following steps.

In step S1, multiple data lines are formed on a side of the substrate.

In step S2, multiple active patterns are formed on a side of the multiple data lines distal to the substrate. The multiple active patterns correspond to the multiple data lines, and each active pattern includes a first conductive section and two second conductive sections disposed on both sides of the first conductive section, and the first conductive section in the active patterns is electrically connected to a data line corresponding to the first conductive section.

In step S3, multiple pixel electrodes are formed on a side of the multiple active patterns distal to the substrate, and two second conductive sections in the active pattern are electrically connected to two different pixel electrodes.

In summary, a method for manufacturing an array substrate according to some embodiments of the present disclosure includes: forming multiple data lines, multiple active patterns, and multiple pixel electrodes on a substrate. The data line is disposed on a side, proximate to the substrate, of the active pattern, and the pixel electrode is located on a side, distal to the substrate, of the active pattern. Therefore, the first conductive section in the active pattern is connected to the data line through a via hole on the side proximate to the substrate, and the second conductive section in the active pattern is connected to the pixel electrode through a via hole on the side distal to the substrate. That is, the via holes for connecting the first conductive section to the data line and the via holes for connecting the pixel electrode to the second conductive section are provided on the two opposite sides of the active pattern in the array substrate. In this way, even if the horizontal distance between the via hole for connecting the first conductive section to the data line and the via hole for connecting the pixel electrode to the second conductive section is small due to the small size of the sub-pixel region, it can be ensured that the two via holes are not connected, thereby avoiding the short-circuit between the data line and the pixel electrode. Further, it can be ensured that the size of the sub-pixel region in the array substrate is no longer affected by the horizontal distance between the two via holes, which makes the size of the sub-pixel region smaller, thereby increasing the PPI of the array substrate. In addition, every two transistors in the array substrate are connected to the same data line through the via holes for connecting the first conductive section to the data line, which effectively reduces the number of via holes for connecting the first conductive section to the data line in the array substrate, ensuring that the number of the via holes does not limit the size of the sub-pixel region, such that the size of the sub-pixel region is further reduced, thereby further increasing the PPI of the array substrate.

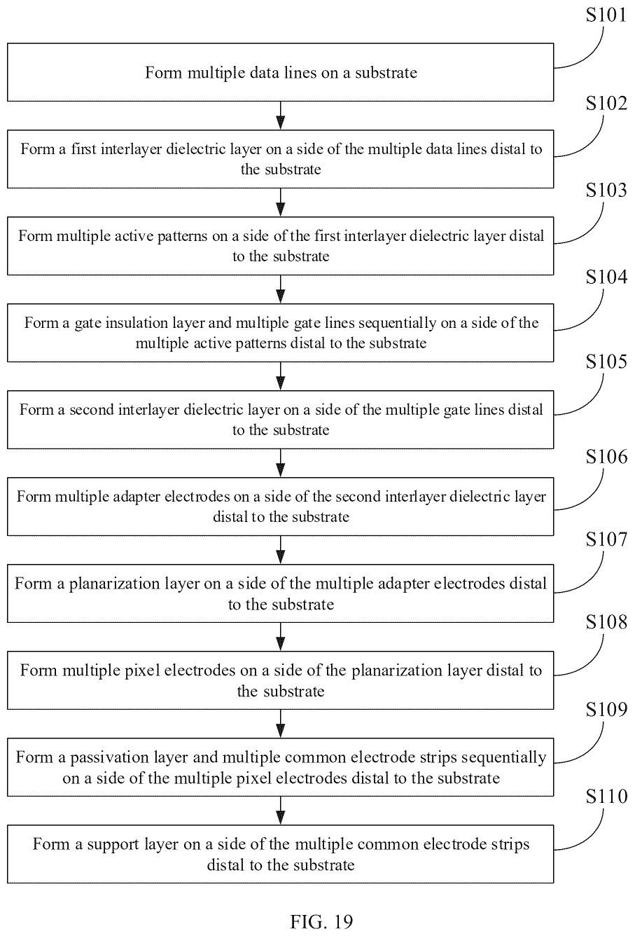

Referring to FIG. 19, FIG. 19 is a flowchart of a method for manufacturing an array substrate according to some embodiments of the present disclosure. The method may be used to manufacture the array substrate illustrated in FIG. 18 and include the following steps.

In step S101, multiple data lines are formed on the substrate, In some embodiments, the substrate may be a glass substrate and the data lines may be made of a metallic material. For example, the data line is made of copper, titanium, molybdenum, or an alloy.

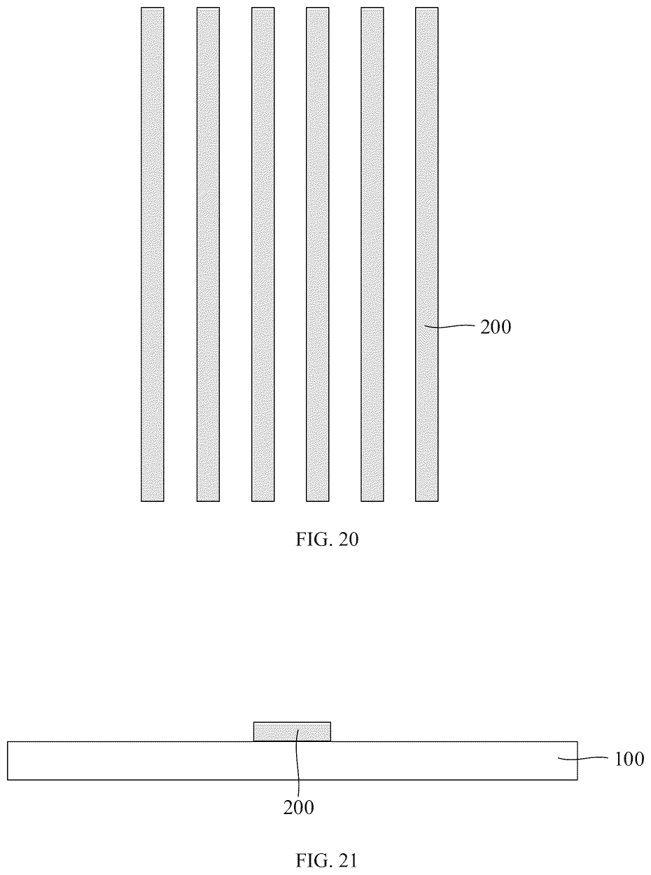

Exemplarily, referring to FIG. 20 and FIG. 21, FIG. 20 is a schematic diagram showing multiple data lines have been formed on a substrate according to some embodiments of the present disclosure, and FIG. 21 is a schematic structural diagram of film layers corresponding to FIG. 20. A metal film is formed on a side of the substrate 100 by depositing, coating, sputtering, or the like. Then, multiple data lines 200 are formed by performing one-time patterning process on the metal film.

In step S102, a first interlayer dielectric layer is formed on a side of the multiple data lines distal to the substrate.

In some embodiments, the first interlayer dielectric layer is made of silicon oxide. Due to the low hydrogen content within the silicon oxide, the first interlayer dielectric layer made of silicon oxide will not conductorize the subsequently formed active pattern directly.

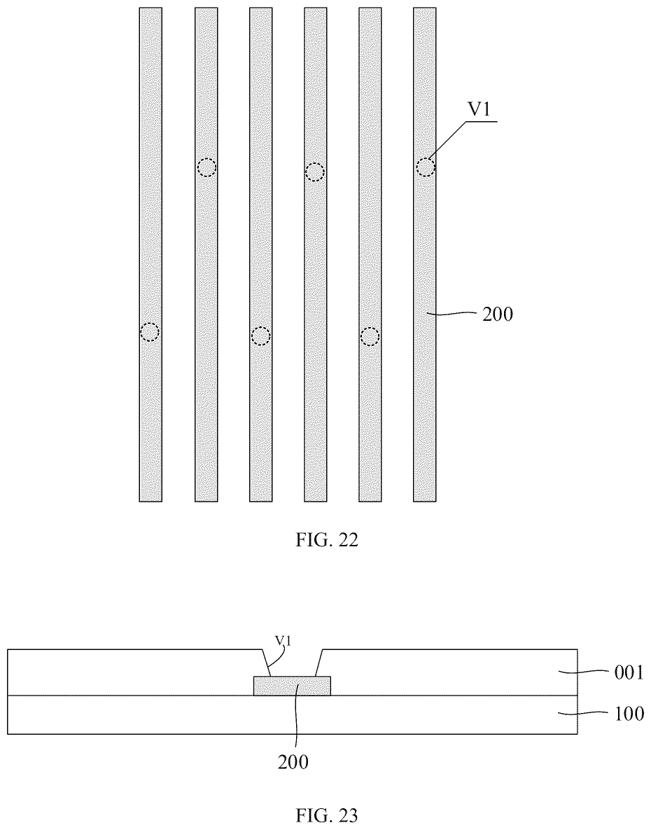

Exemplarily, referring to FIG. 22 and FIG. 23, FIG. 22 is a schematic diagram showing that a first interlayer dielectric layer has been formed according to some embodiments of the present disclosure, and FIG. 23 is a schematic structural diagram of film layers corresponding to FIG. 22. A first interlayer dielectric layer 001 is formed on a side of the multiple data lines 200 distal to the substrate 100 by depositing, coating, sputtering, or the like. Then, multiple first via holes VI are formed within the first interlayer dielectric layer 001 by performing one-time patterning process on the first interlayer dielectric layer 001.

In step S103, multiple active patterns are formed on a side of the first interlayer dielectric layer distal to the substrate.

In some embodiments, the active pattern is made of a transparent oxide semiconductor material. For example, the active pattern is made of indium gallium zinc oxide (IGZO).

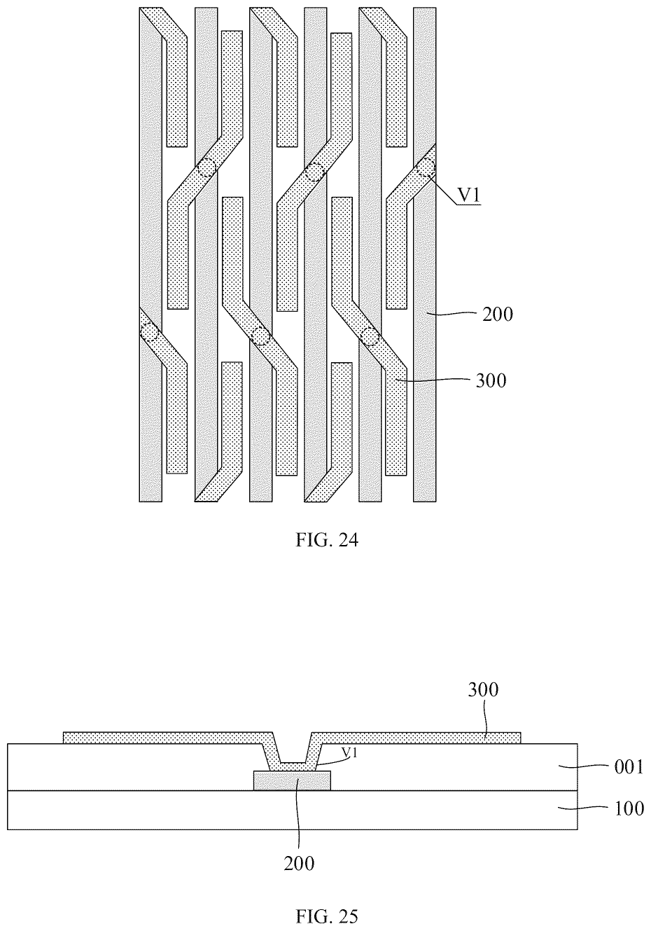

Exemplarily, referring to FIG. 24 and FIG. 25, FIG. 24 is a schematic diagram showing that multiple active patterns have been formed according to some embodiments of the present disclosure, and FIG. 25 is a schematic structural diagram of film layers corresponding to FIG. 24. A semiconductor film is formed on a side of the first interlayer dielectric layer 001 distal to the substrate 100 by depositing, coating, sputtering, or the like. Then, multiple active patterns 300 are formed by performing one-time patterning process on the semiconductor film, and a part of each of the active patterns 300 is extended into the first via hole VI for connecting to a data line 200 corresponding to the active pattern 300.

In step S104, a gate insulation layer and multiple gate lines are sequentially formed on a side of the multiple active patterns distal to the substrate.

In some embodiments, the gate insulation layer is made of silicon oxide such that the active pattern is not directly conductivized. The gate line may be made of a metallic material. For example, the data line is made of copper, titanium, molybdenum, or an alloy.

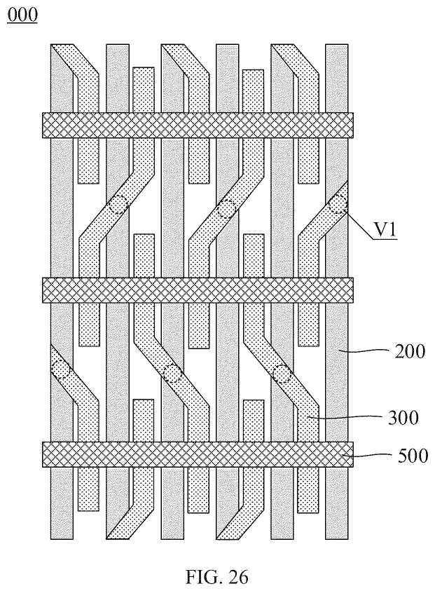

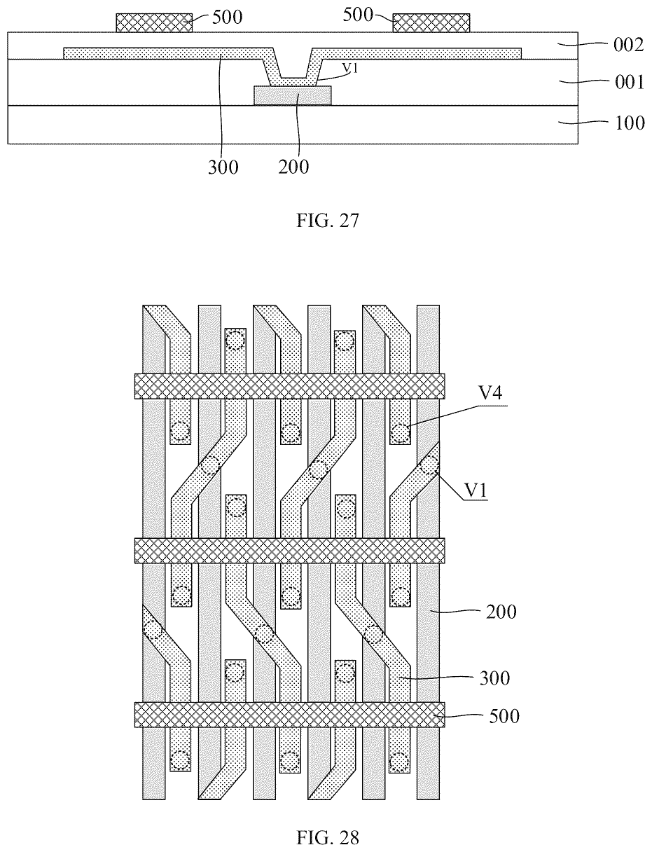

Exemplarily, referring to FIG. 26 and FIG. 27, FIG. 26 is a schematic diagram showing that a gate insulation layer and multiple gate lines have been formed according to some embodiments of the present disclosure, and FIG. 27 is a schematic structural diagram of film layers corresponding to FIG. 26. The gate insulation layer 002 and the metal film are formed sequentially on a side of the multiple active patterns 300 distal to the substrate 100 by depositing, coating, sputtering, or the like. Then, multiple gate lines 500 are formed by performing one-time patterning process on the metal film. The gate lines 500 are insulated from the active patterns 300 by the gate insulation layer 002, and each active pattern 300 may intersect with two adjacent gate lines 500.

In the present disclosure, after the multiple gate lines 500 are formed in the array substrate 000, the multiple active patterns 300 may be subjected to conductorization by taking the multiple gate lines 500 as a mask. After the multiple active patterns 300 are conductorized, the part of the active pattern 300 not covered by the gate line 500 is a conductive section, the portion of the active pattern 300 that is covered by the gate line 500 is a semiconductive section, and the semiconductive section is a channel area in the active pattern 300.

In step S105, a second interlayer dielectric layer is formed on a side of the multiple gate lines distal to the substrate.

In some embodiments, the second interlayer dielectric layer is made of silicon oxide, such that the channel area in the active pattern is not conductive. The thickness of the second interlayer dielectric layer ranges from 4800 angstroms to 5500 angstroms, such that the distance between the subsequently formed transfer electrodes and the gate lines is large, such that the parasitic capacitance between the two is small, thereby reducing the mutual interference between the two.

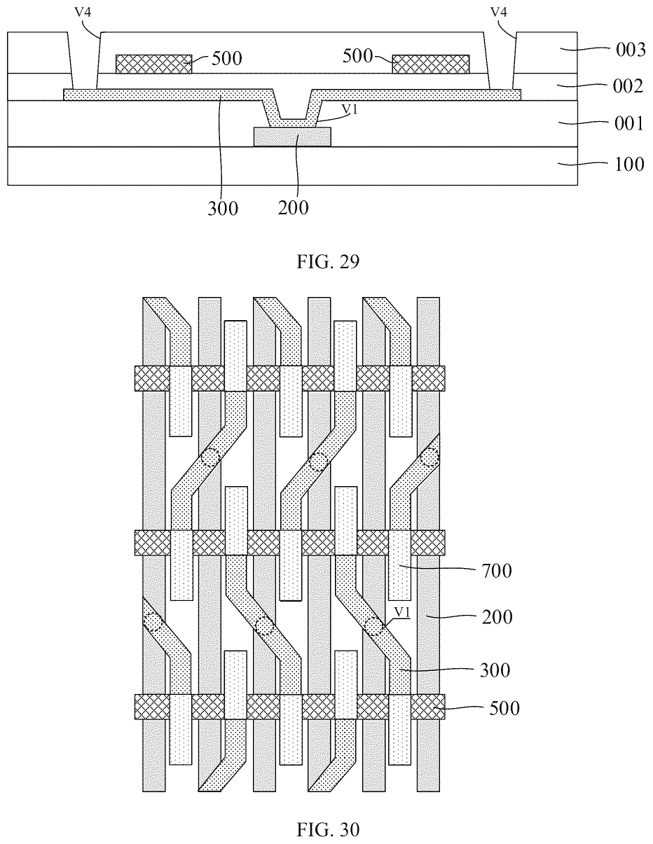

Exemplarily, referring to FIG. 28 and FIG. 29, FIG. 28 is a schematic diagram showing that a second interlayer dielectric layer has been formed according to some embodiments of the present disclosure, and FIG. 29 is a schematic structural diagram of film layers corresponding to FIG. 28. A second interlayer dielectric layer 003 is formed on a side of the multiple gate lines 500 distal to the substrate 100 by depositing, coating, sputtering, or the like. Then multiple fourth via holes V4 are formed in the second interlayer dielectric layer 003 by performing one-time patterning process on the second interlayer dielectric layer 003.

In step S106, multiple transfer electrodes are formed on a side of the second interlayer dielectric layer distal to the substrate.

In some embodiments, the transfer electrodes are made of a transparent conductive material. For example, the transfer electrodes are made of indium tin oxide (ITO).

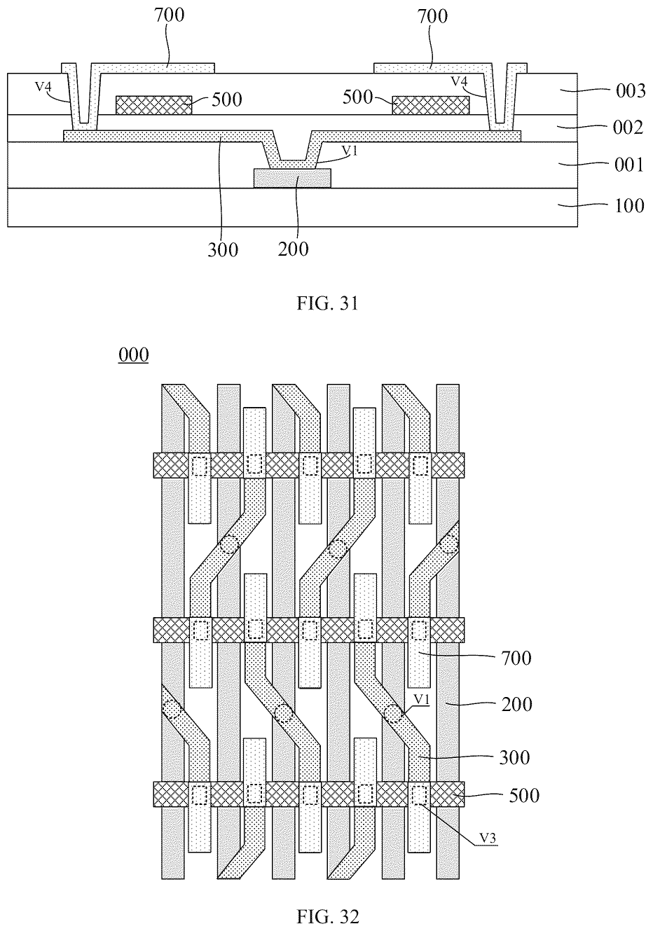

Exemplarily, referring to FIG. 30 and FIG. 31, FIG. 30 is a schematic diagram showing that multiple transfer electrodes have been formed according to some embodiments of the present disclosure, and FIG. 31 is a schematic structural diagram of film layers corresponding to FIG. 30. A transparent conductive film is formed on a side of the second interlayer dielectric layer 003 distal to the substrate 100 by depositing, coating, sputtering, or the like. Then multiple transfer electrodes 700 are formed by performing one-time patterning process on the transparent conductive film. Each of the transfer electrodes 700 is connected to the active pattern 300 through the fourth via hole V4.

In step S107, a planarization layer is formed on a side of the multiple transfer electrodes distal to the substrate.

In some embodiments, the planarization layer is made of an organic material, such as a resin.

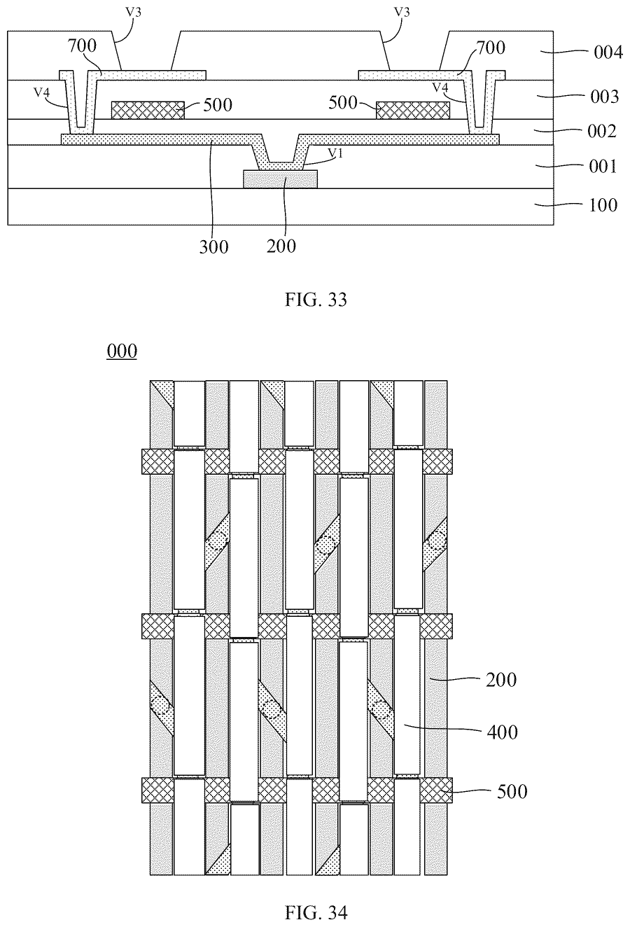

Exemplarily, referring to FIG. 32 and FIG. 33, FIG. 32 is a schematic diagram showing that multiple third via holes have been formed according to some embodiments of the present disclosure, and FIG. 33 is a schematic structural diagram of film layers corresponding to FIG. 32. A planarization layer 004 is formed on a side of the multiple transfer electrodes 700 distal to the substrate 100 by depositing, coating, sputtering, or the like. And then, multiple third via holes V3 are formed within the planarization layer 004 by performing a patterning process on the planarization layer 004. The patterning process may include an exposure process and a development process.

The orthographic projection of the third via hole V3 on the substrate 100 is located within the orthographic projection of the gate 500 on the substrate 100.

In step S108, multiple pixel electrodes are formed on a side of the planarization layer distal to the substrate, In some embodiments, the pixel electrode is made of a transparent conductive material. For example, the pixel electrode is made of ITO.

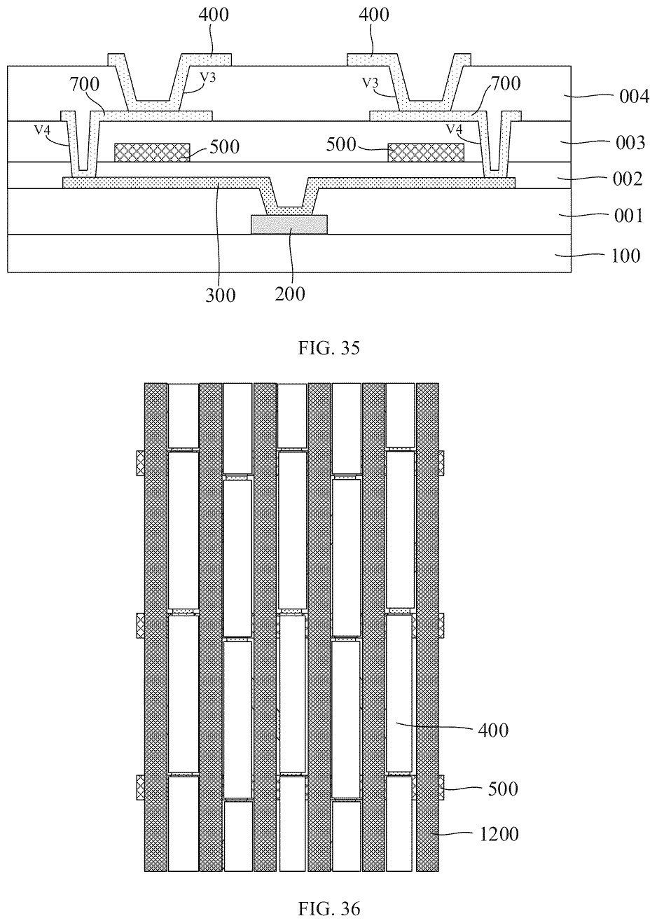

Exemplarily, referring to FIG. 34 and FIG. 35, FIG. 34 is a schematic diagram showing that multiple pixel electrodes have been formed according to some embodiments of the present disclosure, and FIG. 35 is a schematic structural diagram of film layers corresponding to FIG. 34. A transparent conductive film is formed on a side of the planarization layer 004 distal to the substrate 100 by depositing, coating, sputtering, or the like. Then multiple pixel electrodes 400 are formed by performing one-time patterning process on the transparent conductive film. Each of the pixel electrodes 400 is connected to the transfer electrode 700 through the third via hole V3.

In step S109, a passivation layer and multiple common electrode strips are sequentially formed on a side of the multiple pixel electrodes distal to the substrate.

In some embodiments, the passivation layer is made of an inorganic material such as silicon nitride, silicon oxide, or silicon nitride. The common electrode strip is made of a conductive material having light-shielding properties.

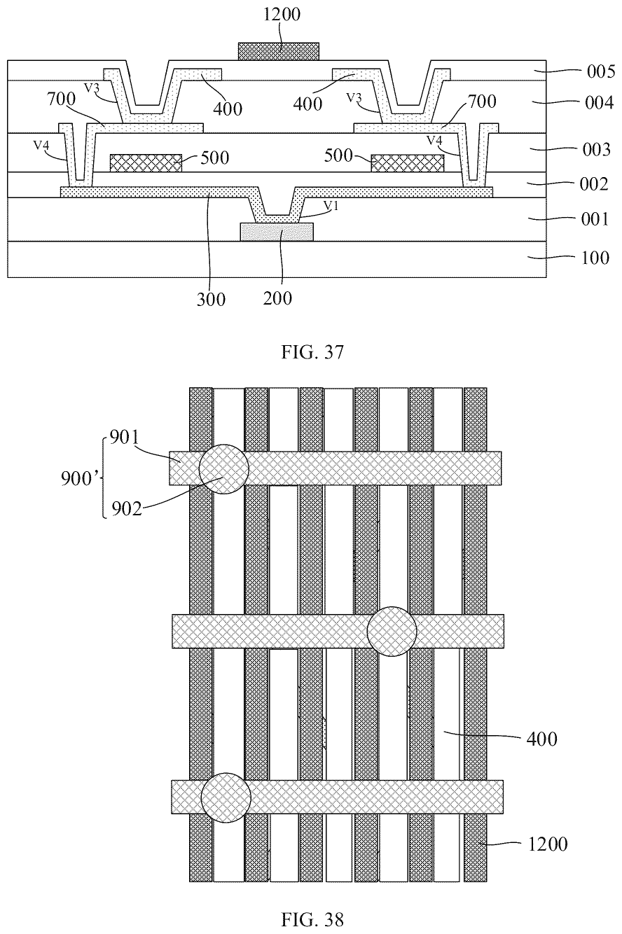

Exemplarily, referring to FIG. 36 and FIG. 37, FIG. 36 is a schematic diagram showing that a passivation layer and multiple common electrode strips have been formed according to some embodiments of the present disclosure, and FIG. 37 is a schematic structural diagram of film layers corresponding to FIG. 36. The passivation layer 005 and the light-shielding conductive film are formed sequentially on a side of the multiple pixel electrodes 400 distal to the substrate by depositing, coating, sputtering, or the like. Then multiple common electrode strips 1200 are formed by performing one-time patterning process on the light-shielding conductive film. An orthographic projection of the multiple common electrode strips 1200 onto the substrate 100 covers the orthographic projection of the data lines 200 onto the substrate 100.

In step S110, a support layer is formed on a side of the multiple common electrode strips distal to the substrate.

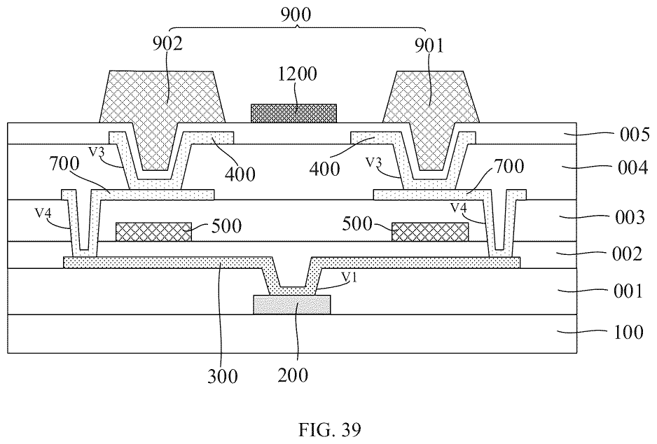

Exemplarily, referring to FIG. 38 and FIG. 39, FIG. 38 is a schematic diagram showing that a support layer has been formed according to some embodiments of the present disclosure, and FIG. 39 is a schematic structural diagram of film layers corresponding to FIG. 38. A support film is formed sequentially on a side of the multiple common electrode strips 1200 distal to the substrate by depositing, coating, sputtering, or the like. Then, the support film is patterned to form a support layer 900 including multiple support strips 900′.

It is to be noted that the one-time patterning process in the above embodiments may include: coating a photoresist, exposing, developing, and removing the photoresist.

In summary, a method for manufacturing an array substrate according to some embodiments of the present disclosure includes: forming multiple data lines, multiple active patterns, and multiple pixel electrodes on a substrate. The data line is disposed on a side, proximate to the substrate, of the active pattern, and the pixel electrode is located on a side, distal to the substrate, of the active pattern. Therefore, the first conductive section in the active pattern is connected to the data line through a via hole on the side proximate to the substrate, and the second conductive section in the active pattern is connected to the pixel electrode through a via hole on the side distal to the substrate. That is, the via holes for connecting the first conductive section to the data line and the via holes for connecting the pixel electrode to the second conductive section are provided on the two opposite sides of the active pattern in the array substrate. In this way, even if the horizontal distance between the via hole for connecting the first conductive section to the data line and the via hole for connecting the pixel electrode to the second conductive section is small due to the small size of the sub-pixel region, it can be ensured that the two via holes are not connected, thereby avoiding the short-circuit between the data line and the pixel electrode. Further, it can be ensured that the size of the sub-pixel region in the array substrate is no longer affected by the horizontal distance between the two via holes, which makes the size of the sub-pixel region smaller, thereby increasing the PPI of the array substrate. In addition, every two transistors in the array substrate are connected to the same data line through the via holes for connecting the first conductive section to the data line, which effectively reduces the number of via holes for connecting the first conductive section to the data line in the array substrate, ensuring that the number of the via holes does not limit the size of the sub-pixel region, such that the size of the sub-pixel region is further reduced, thereby further increasing the PPI of the array substrate.

It is clearly understood by those skilled in the field that, for the convenience and brevity of the description, the film layer structures in the above-described display panel can be referred to the corresponding contents in the foregoing structural embodiments of the display panel, which are not repeated herein.

Embodiments of the present disclosure further provide a liquid crystal display panel. The liquid crystal display panel includes: an array substrate, a color filter substrate oppositely arranged to the array substrate, and a liquid crystal layer disposed between the array substrate and the color filter substrate. The array substrate is illustrated in any one of the above embodiments.

Embodiments of the present disclosure further provide a display device. The display device is: a cell phone, a tablet computer, a television, a monitor, a laptop computer, a digital photo frame, a navigator, and any other product or component with a display function. The display device includes a display panel in the above embodiment and a backlight module, wherein the backlight module is disposed on a side of the array substrate distal to the color filter substrate.

It should be noted that in the accompanying drawings, the dimensions of the layers and regions may be exaggerated for the sake of clarity of illustration. Moreover, it is understood that when an element or layer is referred to as being “on” another element or layer, it may be directly on the other element or there may be intermediate layers. Also, it can be understood that when the element or layer is referred to as being “under” another element or layer, it can be directly under the other element, or more than one intermediate layer or element can exist. It is also understood that when a layer or element is referred to as being “between” two layers or elements, it may be the only layer between the two layers or elements, or more than one intermediate layer or element may also exist. Similar reference marks throughout indicate similar elements.

In this application, the terms “first” and “second” are used for descriptive purposes only and are not to be understood as indicating or implying relative importance. The term “multiple” refers to two or more, unless otherwise expressly limited.

The foregoing descriptions are merely optional embodiments of the present disclosure, and are not intended to limit the present disclosure. Within the spirit and principles of the present disclosure, any modifications, equivalent substitutions, improvements, etc., are within the protection scope of the present disclosure.

1. An array substrate, comprising:
a substrate;
a plurality of data lines disposed on a side of the substrate;
a plurality of active patterns disposed on a side, distal to the substrate, of the plurality of data lines, wherein the plurality of active patterns correspond to the plurality of data lines, and each active pattern comprises a first conductive section and two second conductive sections disposed on two sides of the first conductive section, respectively, and the first conductive section of the active pattern is electrically connected to a data line corresponding to the first conductive section; and
a plurality of pixel electrodes disposed on a side, distal to the substrate, of the plurality of active patterns, wherein the two second conductive sections in the active pattern are electrically connected to two different pixel electrodes, respectively.

2. The array substrate according to claim 1, further comprising a plurality of gate lines disposed on the side, distal to the substrate, of the plurality of active patterns, the gate lines being insulated from the active patterns; wherein
each active pattern further comprises two channel areas disposed between the first conductive section and the two second conductive sections, respectively, wherein the two channel areas in the active pattern correspond to two different the gate lines, and an orthographic projection of each channel area on the substrate overlaps an orthographic projection of the gate line corresponding to the channel area on the substrate; and
two gate lines corresponding to the two channel areas in the active pattern are arranged adjacent to each other.

3. (canceled)

4. The array substrate according to claim 2, wherein the plurality of data lines are arranged sequentially in a first direction, the plurality of gate lines are arranged sequentially in a second direction, the two second conductive sections in each active pattern are respectively arranged on two sides of the data line corresponding to the active pattern in the first direction and respectively arranged on two outer sides of the two gate lines corresponding to the two channel areas in the active pattern in the second direction.

5. The array substrate according to claim 2, wherein the first conductive section in each active pattern comprises a first portion disposed on one side of the data line corresponding to the active pattern, and a second portion disposed on another side of the data line corresponding to the active pattern;
for two adjacent columns of the active patterns, a plurality of first portions in one column of the active patterns and a plurality of second portions in another column of the active patterns are disposed between two adjacent data lines, and are alternately arranged.

6. The array substrate according to claim 5, wherein the two channel areas in each active pattern comprise a first channel area adjacent to the first portion and a second channel area adjacent to the second portion;
in two adjacent rows of the active patterns, a plurality of first channel areas in one row of the active patterns are alternately arranged with a plurality of first channel areas in another row of the active patterns, and the plurality of first channel areas in one row of the active pattern and the plurality of first channel areas in another row of the active patterns are all overlapped with a same first gate line;
wherein the first gate line is one of the plurality of gate lines.

7. The array substrate according to claim 6, wherein in the two adjacent rows of the active patterns, a plurality of second channel areas in one row of the active patterns are all overlapped with a same second gate line, and a plurality of second channel areas in another row of the active patterns are all overlapped with a same third gate line; and
wherein the second gate line is one of the plurality of gate lines disposed on one side of the first gate line, and the third gate line is one of the plurality of gate lines disposed on another side of the first gate line.

8. The array substrate according to claim 2, further comprising a plurality of auxiliary electrodes disposed on the side, distal to the substrate, of the plurality of active patterns, wherein the plurality of auxiliary electrodes are in one-to-one correspondence with the plurality of active patterns, and the first conductive section of each active pattern is connected to the data line corresponding to the active pattern via the auxiliary electrode corresponding to the active pattern.

9. The array substrate according to claim 8, wherein the plurality of auxiliary electrodes and the plurality of gate lines are provided in a same layer and made of a same material.

10. The array substrate according to claim 9, further comprises a first interlayer dielectric layer and a gate insulation layer; wherein
the first interlayer dielectric layer is disposed on the side, distal to the substrate, of the plurality of data lines, the plurality of active patterns are disposed on a side, distal to the substrate, of the first interlayer dielectric layer; the gate insulation layer is disposed on the side, distal to the substrate, of the plurality of active patterns, and the plurality of gate lines and the plurality of auxiliary electrodes are disposed on a side, distal to the substrate, of the gate insulation layer;
wherein the array substrate is provided with a first via hole penetrating through the interlayer dielectric layer and a second via hole penetrating through the gate insulation layer and the first interlayer dielectric layer, the first conductive section is connected to the data line through the first via hole, and the auxiliary electrode is respectively connected to the data line and the first conductive section through the second via hole.

11. The array substrate according to claim 10, wherein a part of an orthographic projection of the second via hole on the substrate is disposed within an orthographic projection of the first via hole on the substrate, and another part is disposed outside the orthographic projection of the first via hole on the substrate.

12. The array substrate according to claim 2, further comprising: a plurality of transfer electrodes one-to-one corresponding to the plurality of pixel electrodes, wherein the plurality of transfer electrodes are disposed between the plurality of active patterns and the plurality of pixel electrodes in a direction perpendicular to the substrate, and each pixel electrode is electrically connected to the second conductive section corresponding to the pixel electrode via the transfer electrode corresponding to the pixel electrode.

13. The array substrate according to claim 12, further comprising: a gate insulation layer, a second interlayer dielectric layer, and a planarization layer; wherein
the gate insulation layer is disposed on the side, distal to the substrate, of the plurality of active patterns, the plurality of gate lines are disposed on a side, distal to the substrate, of the gate insulation layer; the second interlayer dielectric layer is disposed on a side, distal to the substrate, of the plurality of gate lines, the plurality of transfer electrodes are disposed on a side, distal to the substrate, of the second interlayer dielectric layer; the planarization layer is disposed on a side, distal to the substrate, of the plurality of transfer electrodes, and the plurality of pixel electrodes disposed on a side, distal to the substrate, of the planarization layer;
wherein the array substrate is provided with a third via hole penetrating through the planarization layer and a fourth via hole penetrating through the second interlayer dielectric layer and the gate insulation layer, each pixel electrode is connected to the transfer electrode corresponding to the pixel electrode through the third via hole, and the transfer electrode is connected to the second conductive section corresponding to the pixel electrode through the fourth via hole.

14. The array substrate according to claim 13, wherein each transfer electrode comprises a first adapter sub-electrode and a second adapter sub-electrode, an orthographic projection of the first adapter sub-electrode on the substrate being located within an orthographic projection of the gate line on the substrate, and an orthographic projection of the second adapter sub-electrode on the substrate being located outside the orthographic projection of the gate line on the substrate; and
wherein an orthographic projection of the third via hole on the substrate overlaps the orthographic projection of the first adapter sub-electrode on the substrate, and an orthographic projection of the fourth via hole on the substrate overlaps the orthographic projection of the second adapter sub-electrode on the substrate.

15. (canceled)

16. The array substrate according to claim 13, further comprising a passivation layer disposed on a side, distal to the substrate, of the plurality of pixel electrodes, and a support layer disposed on a side, distal to the substrate, of the passivation layer, wherein a part of the support layer is filled in the third via hole, and another part of the support layer projects with respect to the side, distal to the substrate, of the passivation layer.

17. The array substrate according to claim 16, wherein the support layer comprises a plurality of support strips in one-to-one correspondence with the plurality of gate lines, and an orthographic projection of each support strip on the substrate covers the orthographic projection of the gate line corresponding to the support strip on the substrate.

18. The array substrate according to claim 17, wherein the plurality of support strips comprise a plurality of support strip bodies, and support pillars disposed between two adjacent the support strip bodies, a width of the support pillar being greater than a width of the support strip body in an arrangement direction of the plurality of gate lines.

19. The array substrate according to claim 2, further comprising a plurality of auxiliary shading strips disposed on a side, proximate to the substrate, of the plurality of active patterns, wherein the plurality of auxiliary shading strips are in one-to-one correspondence with the plurality of gate lines, an orthographic projection of each auxiliary shading strip on the substrate covers the orthographic projection of the gate line corresponding to the auxiliary shading strip on the substrate, and the orthographic projection of the channel area in the active pattern is located within the orthographic projection of the auxiliary shading strip on the substrate.

20. The array substrate according to claim 1, further comprising a plurality of common electrode strips disposed on a side, distal to the substrate, of the plurality of pixel electrodes, wherein the common electrode strips have light-shielding property, the plurality of common electrode strips are in one-to-one correspondence with the plurality of data lines, and an orthographic projection of each common electrode strip on the substrate cover an orthographic projection of the data line corresponding to the common electrode strip on the substrate.

21. A method for manufacturing an array substrate, comprising:
forming a plurality of data lines on a side of the substrate;
forming a plurality of active patterns on a side, distal to the substrate, of the plurality of data lines, wherein the plurality of active patterns correspond to the plurality of data lines, and each active pattern comprises a first conductive section and two second conductive sections disposed on two sides of the first conductive section, respectively, and the first conductive section of the active pattern is electrically connected to a data line corresponding to the first conductive section;
forming a plurality of pixel electrodes on a side, distal to the substrate, of the plurality of active patterns, wherein the two second conductive sections in the active pattern are electrically connected to two different pixel electrodes.

22. A display panel, comprising: an array substrate, a color filter substrate oppositely arranged to the array substrate, and a liquid crystal layer disposed between the array substrate and the color filter substrate_ wherein
the array substrate comprises:
a substrate;
a plurality of data lines disposed on a side of the substrate;
a plurality of active patterns disposed on a side, distal to the substrate, of the plurality of data lines, wherein the plurality of active patterns correspond to the plurality of data lines, and each active pattern comprises a first conductive section and two second conductive sections disposed on two sides of the first conductive section, respectively, and the first conductive section of the active pattern is electrically connected to a data line corresponding to the first conductive section; and
a plurality of pixel electrodes disposed on a side, distal to the substrate, of the plurality of active patterns, wherein the two second conductive sections in the active pattern are electrically connected to two different pixel electrodes, respectively.
